(19) United States
(12) Patent Application Publication
(10) Pub. No.: US 2014/0021428 A1
(43) Pub. Date: Jan. 23, 2014

(54) SEMICONDUCTOR DEVICE AND MANUFACTURING METHOD THEREFOR

(71) Applicant: ELPIDA MEMORY, INC., Tokyo (JP)

(72) Inventors: Tomoyasu KAKEGAWA, Tokyo (JP); Takao Adachi, Tokyo (JP); Yoshinori Tanaka, Tokyo (JP)

(21) Appl. No.: 13/944,576

(22) Filed: Jul. 17, 2013

(30) Foreign Application Priority Data
Jul. 18, 2012 (JP) 2012-159527

(51) Int. Cl. H01L 27/24; H01L 29/66

(52) U.S. Cl. CPC H01L 27/2436; H01L 29/66477
USPC 257/2; 438/238

(57) ABSTRACT

A semiconductor device comprises a first transistor including a first diffusion region, a first body region, and a second diffusion region, formed to align in a direction orthogonal to a main surface; a second transistor including a third diffusion region, a second body region, and a fourth diffusion region, formed to align in a direction orthogonal to the main surface; a first variable resistance element provided in the second diffusion region of the first transistor; a second variable resistance element provided in the fourth diffusion region of the second transistor; a bit line commonly connected to the first variable resistance element and the second variable resistance element; a first word line arranged on a first side of the first body region; a second word line arrange between a second side of the first body region and a first side of the second body region; and a third word line arranged on a second side of the second body region.

### REFERENCE TO RELATED APPLICATION

This application is based upon and claims the benefit of priority of Japanese patent application No. 2012-159527, filed on Jul. 18, 2012, the disclosure of which is incorporated herein in its entirety by reference thereto.

### TECHNICAL FIELD

The present invention relates to a semiconductor device and a method of manufacturing the same.

### BACKGROUND

Improvements in integration density of semiconductor devices have been principally achieved by reduction in flat surface with regard to transistor size. However, there is a risk that with further reduction in flat surface with regard to transistor size, a device will no longer operate correctly due to short channel effects or the like. Accordingly, a method is proposed in which a semiconductor substrate is sterically manufactured and transistors are formed three-dimensionally. For example, Patent Literature 1 discloses a semiconductor device that uses a three-dimensional transistor of longitudinal structure type, having silicon pillars as a channel, the pillars extending in a vertical direction with respect to the main surface of the semiconductor substrate.

### [Patent Literature 1]

JP Patent Kokai Publication No. JP-P2011-77185A, which corresponds to US2011/073939 A1.

### [Non-Patent Literature 1]

Wookhyun Kwon, Tsu-Jae King Liu, “A Highly Scalable Capacitor-Less Cell Having a Doubly Gated Vertical Channel”, Jpn. J. Appl. Phys. 49 (2010) 04DD04.

### DISCUSSION OF RELATED ART

The entire disclosures of Patent Literature 1 and Non-Patent Literature 1 are incorporated herein by reference thereto. The following analysis is given by the inventors of the present application.

A three-dimensional transistor described in Patent Literature 1 has a structure in which wiring (second wiring 17 in FIG. 21 of Patent Literature 1) is separated in a narrow section between adjacent transistors, and it is expected that if the space between the transistors is further narrowed, separating the wiring in question will become difficult.

### SUMMARY

According to a first aspect of the present invention there is provided: a semiconductor device comprising: a first transistor including a first diffusion region of a first conduction type, a first body region of a second conduction type, and a second diffusion region of the first conduction type, formed and arranged in a direction orthogonal to a main surface side by side; a second transistor including a third diffusion region of the first conduction type, a second body region of the second conduction type, and a fourth diffusion region of the first conduction type, formed and arranged in a direction orthogonal to the main surface side by side; a first variable resistance element provided in the second diffusion region of the first transistor; a second variable resistance element provided in the fourth diffusion region of the second transistor; a bit line commonly connected to the first variable resistance element and the second variable resistance element; a first word line arranged on a first side of the first body region; a second word line arrange between a second side of the first body region and a first side of the second body region; and a third word line arranged on a second side of the second body region.

According to a second aspect of the present invention there is provided a method of manufacturing a semiconductor device, comprising: forming a plurality of pillars by forming a groove, in a semiconductor substrate having at least, in a first diffusion region of a first conduction type, a body region of a second conduction type, the groove being deeper than a boundary face of the first diffusion region and the body region; forming an interlayer insulating film whose upper face is lower than the boundary face of the first diffusion region and the body region, on the body region between the pillars; forming a gate insulating film on a sidewall face of the pillars at a position higher than the upper face of the interlayer insulating film; forming a word line whose upper face is lower than an upper face of the pillars, on the interlayer insulating film between the gate insulating films; forming a second diffusion region of the first conduction type by injecting impurities from an upper face side into the body region of the pillars; and forming a variable resistance element in the second diffusion region.

According to a third aspect of the present invention there is provided a method of manufacturing a semiconductor device, comprising: forming a plurality of first grooves in a semiconductor substrate having a body region of a second conduction type; forming an insulating film on a sidewall face and a bottom face of the first grooves; forming a first interlayer insulating film of a prescribed height on the insulating film between the first grooves; forming a sidewall that covers the insulating film with respect to the first interlayer insulating film; exposing part of the insulating film by etching part of the first interlayer insulating film; forming a hole to the body region in the insulating film exposed from a first sidewall face of the first groove by masking a second sidewall face thereof; removing the sidewall; forming a source line of a prescribed height on the first interlayer insulating film between the first grooves; forming a first diffusion region of a first conduction type by diffusing impurities included in the source line in the body region; forming a plurality of pillars by forming a second groove shallower than the first grooves; forming a second interlayer insulating film of a prescribed height on the semiconductor substrate between the pillars; forming a gate insulating film on a side wall face of the pillars at a position higher than an upper face of the second interlayer insulating film; forming a word line whose upper face is lower than an upper face of the pillars, on the first interlayer insulating film between the gate insulating films; forming a second diffusion region of the first conduction type by injecting impurities from an upper face side into the body region of the pillars; and forming a variable resistance element in the second diffusion region.

### BRIEF DESCRIPTION OF THE DRAWINGS

FIG. 1 is a cross sectional diagram schematically showing a configuration of a memory cell in a semiconductor device according to a first exemplary embodiment of the present disclosure;

FIG. 2 is a block diagram schematically showing a circuit configuration of the semiconductor device according to the first exemplary embodiment of the disclosure;

FIG. 3 is a circuit diagram schematically showing a configuration of a memory cell array in the semiconductor device according to the first exemplary embodiment of the disclosure;

FIG. 4 is a current voltage characteristic diagram of a selected cell and an unselected cell for describing operation of a memory cell in the semiconductor device according to the first exemplary embodiment of the disclosure;

FIG. 5A is a plan view, FIG. 5B is a cross sectional view at X-X′, and FIG. 5C is a cross sectional view at Y-Y′, for describing a method of manufacturing the semiconductor device according to the first exemplary embodiment of the disclosure;

FIG. 6A is a plan view, FIG. 6B is a cross sectional view at X-X′, and FIG. 6C is a cross sectional view at Y-Y′, continuing from FIGS. 5A, 5B and 5C, for describing a method of manufacturing the semiconductor device according to the first exemplary embodiment of the disclosure;

FIG. 7A is a plan view, FIG. 7B is a cross sectional view at X-X′, and FIG. 7C is a cross sectional view at Y-Y′, continuing from FIGS. 6A, 6B and 6C, for describing a method of manufacturing the semiconductor device according to the first exemplary embodiment of the disclosure;

FIG. 8A is a plan view, FIG. 8B is a cross sectional view at X-X′, and FIG. 8C is a cross sectional view at Y-Y′, continuing from FIGS. 7A, 7B and 7C, for describing a method of manufacturing the semiconductor device according to the first exemplary embodiment of the disclosure;

FIG. 9A is a plan view, FIG. 9B is a cross sectional view at X-X′, and FIG. 9C is a cross sectional view at Y-Y′, continuing from FIGS. 8A, 9B and 9C, for describing a method of manufacturing the semiconductor device according to the first exemplary embodiment of the disclosure;

FIG. 10A is a plan view, FIG. 10B is a cross sectional view at X-X′, and FIG. 10C is a cross sectional view at Y-Y′, continuing from FIGS. 9A, 9B and 9C, for describing a method of manufacturing the semiconductor device according to the first exemplary embodiment of the disclosure;

FIG. 11A is a plan view, FIG. 11B is a cross sectional view at X-X′, and FIG. 11C is a cross sectional view at Y-Y′, continuing from FIGS. 10A, 10B and 10C, for describing a method of manufacturing the semiconductor device according to the first exemplary embodiment of the disclosure;

FIG. 12A is a plan view, FIG. 12B is a cross sectional view at X-X′, and FIG. 12C is a cross sectional view at Y-Y′, continuing from FIGS. 11A, 11B and 11C, for describing a method of manufacturing the semiconductor device according to the first exemplary embodiment of the disclosure;

FIG. 13A is a plan view, FIG. 13B is a cross sectional view at X-X′, and FIG. 13C is a cross sectional view at Y-Y′, continuing from FIGS. 12A, 12B and 12C, for describing a method of manufacturing the semiconductor device according to the first exemplary embodiment of the disclosure;

FIG. 14A is a plan view, FIG. 14B is a cross sectional view at X-X′, and FIG. 14C is a cross sectional view at Y-Y′, continuing from FIGS. 13A, 13B and 13C, for describing a method of manufacturing the semiconductor device according to the first exemplary embodiment of the disclosure;

FIG. 15A is a plan view, FIG. 15B is a cross sectional view at X-X′, and FIG. 15C is a cross sectional view at Y-Y′, continuing from FIGS. 14A, 14B and 14C, for describing a method of manufacturing the semiconductor device according to the first exemplary embodiment of the disclosure;

FIG. 16A is a plan view, FIG. 16B is a cross sectional view at X-X′, and FIG. 16C is a cross sectional view at Y-Y′, continuing from FIGS. 15A, 15B and 15C, for describing a method of manufacturing the semiconductor device according to the first exemplary embodiment of the disclosure;

FIG. 17A is a plan view, FIG. 17B is a cross sectional view at X-X′, and FIG. 17C is a cross sectional view at Y-Y′, continuing from FIGS. 16A, 16B and 16C, for describing a method of manufacturing the semiconductor device according to the first exemplary embodiment of the disclosure;

FIG. 18A is a plan view, FIG. 18B is a cross sectional view at X-X′, and FIG. 18C is a cross sectional view at Y-Y′, schematically showing a configuration of a semiconductor device according to a second exemplary embodiment of the disclosure;

FIG. 19 is a circuit diagram schematically showing a configuration of a memory cell array in the semiconductor device according to the second exemplary embodiment of the disclosure;

FIG. 20A is a plan view, FIG. 20B is a cross sectional view at X-X′, and FIG. 20C is a cross sectional view at Y-Y′, for describing a method of manufacturing the semiconductor device according to the second exemplary embodiment of the disclosure;

FIG. 21A is a plan view, FIG. 21B is a cross sectional view at X-X′, and FIG. 21C is a cross sectional view at Y-Y′, continuing from FIGS. 20A, 20B and 20C, for describing a method of manufacturing the semiconductor device according to the second exemplary embodiment of the disclosure;

FIG. 22A is a plan view, FIG. 22B is a cross sectional view at X-X′, and FIG. 22C is a cross sectional view at Y-Y′, continuing from FIG. 21, for describing a method of manufacturing the semiconductor device according to the second exemplary embodiment of the disclosure;

FIG. 23A is a plan view, FIG. 23B is a cross sectional view at X-X′, and FIG. 23C is a cross sectional view at Y-Y′, continuing from FIGS. 22A, 22B and 22C, for describing a method of manufacturing the semiconductor device according to the second exemplary embodiment of the disclosure;

FIG. 24A is a plan view, FIG. 24B is a cross sectional view at X-X′, and FIG. 24C is a cross sectional view at Y-Y′, continuing from FIGS. 23A, 23B and 23C, for describing a method of manufacturing the semiconductor device according to the second exemplary embodiment of the disclosure;

FIG. 25A is a plan view, FIG. 25B is a cross sectional view at X-X′, and FIG. 25C is a cross sectional view at Y-Y′, continuing from FIGS. 24A, 24B and 24C, for describing a method of manufacturing the semiconductor device according to the second exemplary embodiment of the disclosure;

FIG. 26A is a plan view, FIG. 26B is a cross sectional view at X-X′, and FIG. 26C is a cross sectional view at Y-Y′, continuing from FIGS. 25A, 25B and 25C, for describing a method of manufacturing the semiconductor device according to the second exemplary embodiment of the disclosure;

FIG. 27A is a plan view, FIG. 27B is a cross sectional view at X-X′, and FIG. 27C is a cross sectional view at Y-Y′, continuing from FIGS. 26A, 26B and 26C, for describing a method of manufacturing the semiconductor device according to the second exemplary embodiment of the disclosure; and

FIG. 28A is a plan view, FIG. 28B is a cross sectional view at X-X′, and FIG. 28C is a cross sectional view at Y-Y′, continuing from FIGS. 27A, 27B and 27C, for describing a method of manufacturing the semiconductor device according to the second exemplary embodiment of the disclosure.

### PREFERRED MODES

### First Exemplary Embodiment

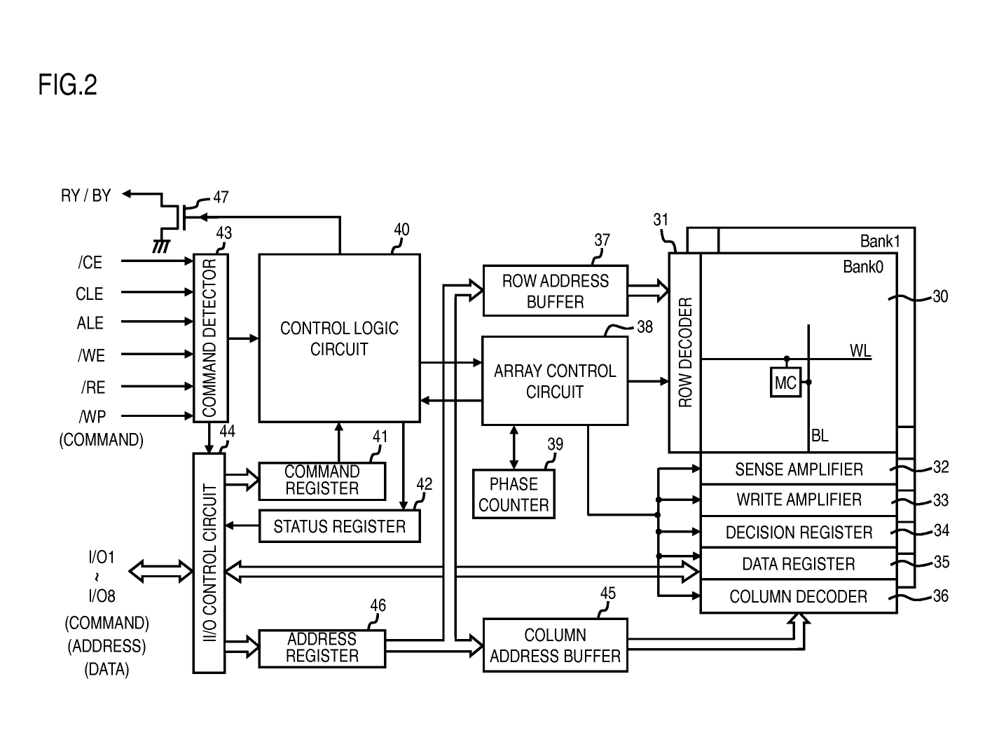

A description is given concerning a semiconductor device according to a first exemplary embodiment of the present disclosure, making use of the drawings. FIG. 2 is a block diagram schematically showing a circuit configuration of the semiconductor device according to the first exemplary embodiment of the disclosure.

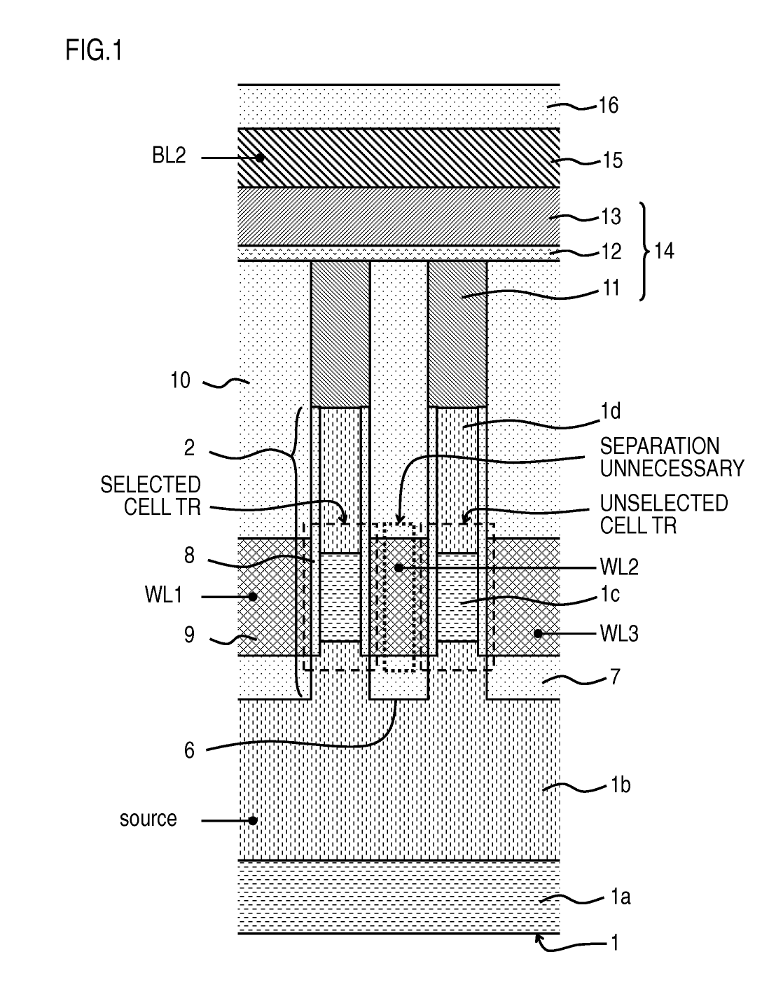

The semiconductor device is provided with a memory circuit. The semiconductor device includes, as the memory circuit, a memory cell array 30 divided into a plurality of banks Bank0 to Bank1, a row decoder 31, a sense amplifier 32, a write amplifier 33, a decision register 34, a data register 35, and a column decoder 36, associated with the respective banks Bank0 to Bank1. In addition, the semiconductor device includes, as peripheral circuitry formed around the memory circuit, a row address buffer 37, an array control circuit 38, a phase counter 39, a control logic circuit 40, a command register 41, a status register 42, a command detector 43, an I/O control circuit 44, a column address buffer 45, an address register 46, and a transistor 47. It is to be noted that in the example of FIG. 1, two banks Bank0 to Bank1 are provided, but there is no particular limitation to the number of banks. Furthermore, although not shown in the drawings, external power supply voltages VDD and VSS are supplied to the semiconductor device from outside.

The memory cell array 30 is a circuit arranged to have a plurality of memory cells MC arrayed in a row direction and a column direction. The memory cell array 30 includes a plurality of word lines WL extending in a first direction and aligned in a second direction (a direction orthogonal to the first direction), a plurality of bit lines BL extending in the second direction and aligned in the first direction, and a plurality of memory cells MC arranged close to respective intersection points of the word lines WL and the bit lines BL. The word lines WL are connected to the row decoder 31. The respective bit lines BL are connected to a sense amplifier. Details of the memory cell array 30 and the memory cell MC are described later.

The row decoder 31 is a circuit that activates a corresponding word line WL based on a signal from the array control circuit 38 and the row address buffer 37.

The sense amplifier 32 is a circuit that amplifies electrical potential of data read correspondingly to the word line WL from the memory cell array 30, based on a signal from the array control circuit 38. The sense amplifier 32 outputs the data whose electrical potential is amplified, to the data register 35 and the decision register 34.

The write amplifier 33 is a circuit that amplifies the electrical potential of data from the data register 35, based on a signal from the array control circuit 38. The write amplifier 33 outputs the data whose electrical potential is amplified, to the memory cell array 30 and the decision register 34 via a word line WL.

The decision register 34 is a register that makes a pass or fail decision (verify operation) by comparing write data of the write amplifier 33 and read data of the sense amplifier 32, based on a signal from the array control circuit 38. In a case where the decision register 34 detects a fail, writing to the memory cell array 30 is performed again, and a loop of such re-writing and reading is repeated until the decision register 34 detects a pass.

The data register 35 is a register that holds data. The data register 35 sends/receives data to/from the I/O control circuit 44. The data register 35 holds data from the I/O control circuit 44 or the sense amplifier 32. The data register 35, when writing, outputs the data to the write amplifier 33, based on a signal from the array control circuit 38. The data register 35, when reading, outputs the data to the I/O control circuit 44, based on a signal from the array control circuit 38.

The column decoder 36 is a circuit that selects a bit line BL in the memory cell array in response to a column address, the column address is determined based on respective signals from the array control circuit 38 and the column address buffer 45.

The row address buffer 37 is a buffer that holds a row address among addresses from the address register 46. The row address buffer 37 outputs the row address it holds to the row decoder 31.

The array control circuit 38 is a circuit that controls respective operations of the row decoder 31, the sense amplifier 32, the write amplifier 33, the decision register 34, the data register 35, and the column decoder 36, based on a signal from the control logic circuit 40 and the phase counter 39. The array control circuit 38 supplies a word line selection signal to the row decoder 31, supplies a bit line selection signal to the column decoder 36, and supplies various control signals to the sense amplifier 32, the write amplifier 33, the decision register 34, and the data register 35.

The phase counter 39 is a counter for controlling phase of an access target.

The control logic circuit 40 is a logic circuit that outputs various control signals to peripheral circuitry. The control logic circuit 40 outputs the various control signals to the array control circuit 38, the status register 42, and the transistor 47, based on a signal from the command detector 43 and the command register 41. The control logic circuit 40 sends/receives signals to/from the array control circuit 38.

The command register 41 is a register that holds a command from the I/O control circuit 44. The command register 41 outputs the command to the control logic circuit 40.

The status register 42 is a register that holds a status signal that indicates status of the device from the control logic circuit 40. The status register 42 outputs the status signal to the I/O control circuit 44. Here the status includes the pass and fail in a write operation.

The command detector 43 is a circuit that receives a command (chip enable /CE, command latch enable CLE, address latch enable ALE, write enable /WE, read enable /RE, /WP).

Here, /CE is a device selection signal, the device goes to a standby mode when the /CE takes a High level in a read state.

CLE is a signal for controlling reception of a command by the command register 41. When CLE going to a High level, /WE takes a High level and /WE takes a Low level, data appeared at I/O terminals (I/O1 to I/O8) are received by the command register 41 as a command.

ALE is a signal for controlling reception of an address or data by the address register 46 or the data register 35 within the device. When ALE going to a High level, /WE takes a High level and /WE takes a Low level, data appeared at the I/O terminals (I/O1 to I/O8) are received by the address register 46 as address data. By ALE going to a Low level, data at the I/O terminals (I/O1 to I/O8) are received by the data register 35 as input data to be stored in the memory cells.

/WE is a write signal for data from the I/O terminal (I/O1 to I/O8) to be received into the device.

/RE is a signal for outputting data (serial output).

/WP is a control signal for prohibiting writing and deleting operations, to protect data. Normally, /WP=High, and when power is turned on/off, /WP=Low.

The I/O control circuit 44 is a circuit that receives commands, addresses and data from the I/O terminals and that sends data from the memory cells to the I/O terminals. The I/O control circuit 44 outputs a command to the command register 41. The I/O control circuit 44 outputs an address to the address register 46. The I/O control circuit 44 sends/receives data to/from the data register 35. The operation of the I/O control circuit 44 is determined based on a signal from the command detector 43 and the status register 42.

Here, the I/O terminals I/O1 to I/O8 are terminals (ports) that input or output addresses, commands and data.

The column address buffer 45 is a buffer that holds a column address sent from the address register 46. The column address buffer 45 outputs the column address to the column decoder 36.

The address register 46 is a register that holds an address from the I/O control circuit 44. The address register 46 outputs a row address to the row address buffer 37. The address register 46 outputs a column address to the column address buffer 45.

The transistor 47 is an nMOS transistor of an open drain configuration. A gate of the transistor 47 is connected to the control logic circuit 40. A source of the transistor 47 is connected to ground. A drain of the transistor 47 is connected to an output terminal for an internal state notification signal RY/BY. The gate of the transistor 47 is at a High electrical potential during execution of an operation such as a program/deletion/read operation. With regard to the gate of the transistor 47, when turned on (conductive), RY/BY=Low (Busy), and when an operation is completed, electrical potential is Low, RY/BY is pulled up to a power supply potential, and RY/BY=High (Ready).

Here, RY/BY is a signal to notify the internal state of the device to the outside.

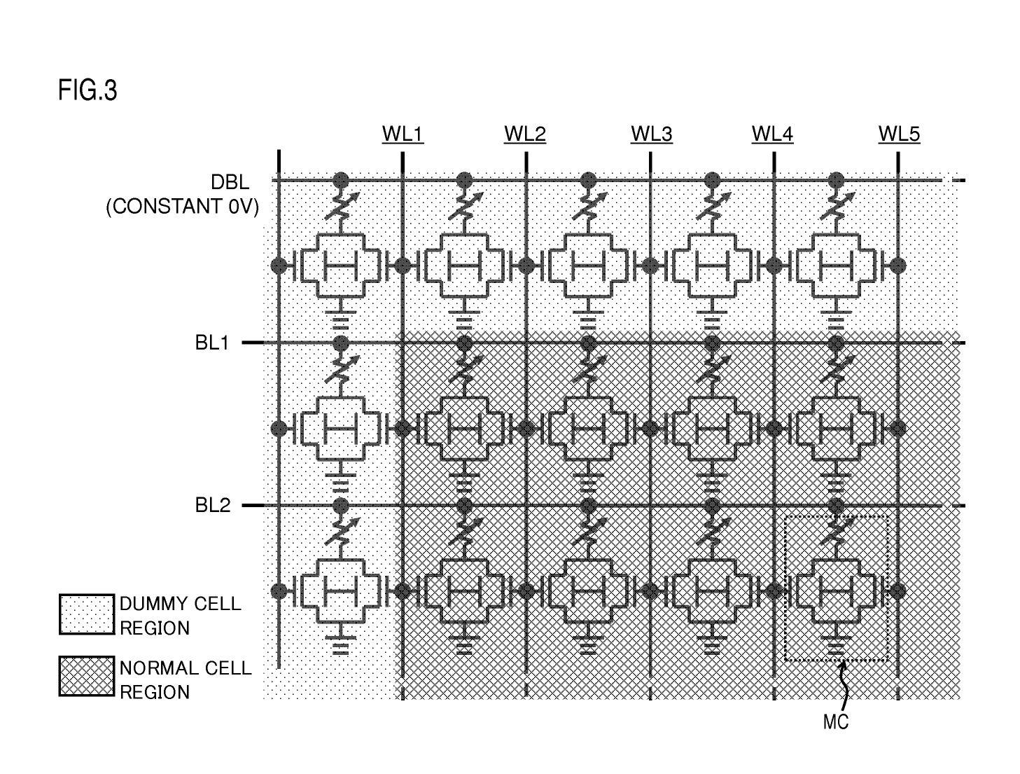

FIG. 3 is a circuit diagram schematically showing a configuration of the memory cell array in the semiconductor device according to the first exemplary embodiment of the present disclosure.

The memory cell array (30 in FIG. 2) includes a plurality of word lines WL1 to WL5 extending in a first direction and aligned in a second direction (a direction orthogonal to the first direction), a plurality of bit lines DBL, BL1, and BL2 extending in the second direction and aligned in the first direction, and a plurality of memory cells MC arranged close to respective intersection points of the word lines and the bit lines. DBL is a dummy bit line that is configured to keep a 0V. BL1 and BL2 are controlled by the column decoder (36 in FIG. 2). WL1 to WL5 are controlled by the row decoder (31 in FIG. 2). An MC has two MOS transistors (Tr in FIG. 1); a common source of the respective MOS transistors is electrically connected to ground; the respective MOS transistors have a common channel; respective gates of the respective MOS transistors are electrically connected to separate word lines, and the common source of the respective MOS transistors is electrically connected to a corresponding bit line via a storage element (14 in FIG. 1).

FIG. 1 is a cross sectional diagram schematically showing a configuration of a memory cell in the semiconductor device according to the first exemplary embodiment of the present disclosure.

The memory cell (MC in FIG. 3) includes a three-dimensional transistor Tr of a longitudinal structure type, using, as a channel, pillars 2 extending in a vertical (orthogonal) direction with respect to a main surface, and a variable resistance element 14 that is the storage element. The memory cell includes a semiconductor substrate 1 having a p-type diffusion region 1a, an n-type diffusion region 1b, a p-type body region 1c, and an n-type diffusion region 1d, stacked in this order from the bottom. The semiconductor substrate 1 has groove(s) 6 formed in the n-type diffusion region 1d, the p-type body region 1c and a portion of the n-type diffusion region 1b. The grooves 6 are formed in a mesh-like pattern when viewed in the vertical direction with respect to the main surface, and a bottom face thereof is arranged in a middle part of the n-type diffusion region 1b. Between the grooves 6 the pillars 2 are formed in a columnar shape, with the n-type diffusion region 1b, the p-type body region 1c, and the n-type diffusion region 1d being stacked. The n-type diffusion region 1b section in the pillars 2 forms a common source of two MOS transistors and is electrically connected to ground (0V). A section of the p-type body region 1c in the pillars 2 forms a common channel of the two MOS transistors, and is floating with respect to a base part of the semiconductor substrate 1 (the p-type diffusion region 1a and a section of the n-type diffusion region 1b outside of the pillars 2). Sections of the n-type diffusion region 1d in the pillars 2 form a common drain of the two MOS transistors and is electrically connected to the variable resistance element 14.

An interlayer insulating film 7, a word line 9, and an interlayer insulating film 10 are stacked in this order from the bottom, on the bottom face of the groove 6. A gate insulating film 8 is formed on both side wall faces of a section above the upper face of the interlayer insulating film 7 on the pillar 2. The word line 9 is laid out via the gate insulating film 8 on a side of the p-type body region 1c forming a channel. In FIG. 1, WL1, among the word lines 9, is arranged on a first side of the p-type body region 1c of the pillar 2 on the left side. WL2, among the word lines 9, is arranged between a second side of the p-type body region 1c of the pillar 2 on the left side and a first side of the p-type body region 1c of the pillar on the right side. WL3, among the word lines 9, is arranged on a second side of the p-type body region 1c of the pillar 2 on the right side. WL2 is not separated between adjacent pillars 2. In this way, it is possible to perform a selection operation by activating two word lines 9 from both sides with respect to the pillars 2, for a memory cell that is desired to be selected (selected cell Tr). WL1, WL2 and WL3 are electrically independent from each other, and are electrically connected to the row decoder (31 in FIG. 2). The interlayer insulating film 10 is formed above the upper face of the pillars 2. In the interlayer insulating film 10, a hole is formed leading to the n-type diffusion region 1d, and a contact plug 11 is embedded in the hole.

A variable resistance film 12, an upper electrode film 13, and a bit line 15 are stacked in this order from the bottom, on the interlayer insulating film 10 including the contact plug 11. The variable resistance film 12, the upper electrode film 13, and the bit line 15 are formed to extend in a direction orthogonal to the direction in which the word lines 9 extend. The variable resistance film 12 is in contact with the contact plug 11 that forms a lower electrode. The contact plug 11, the variable resistance film 12 and the upper electrode film 13 form the variable resistance element 14. It is to be noted that in a memory cell such as a ReRAM or a PRAM, since there is no resistance variation even if some current flows in an unselected memory cell, the variable resistance element 14 may be preferably used as a storage element. However, this does not deny application to a DRAM. The contact plug 11 is electrically connected to the variable resistance film 12 and the n-type diffusion region 1d of a corresponding pillar 2. With respect to the variable resistance element 14, the variable resistance film 12 and the upper electrode film 13 are common to adjacent memory cells. The bit line 15 is electrically connected to the column decoder (36 in FIG. 2). The interlayer insulating film 16 is formed on the interlayer insulating film 10 including the variable resistance film 12, the upper electrode film 13, and the bit line 15.

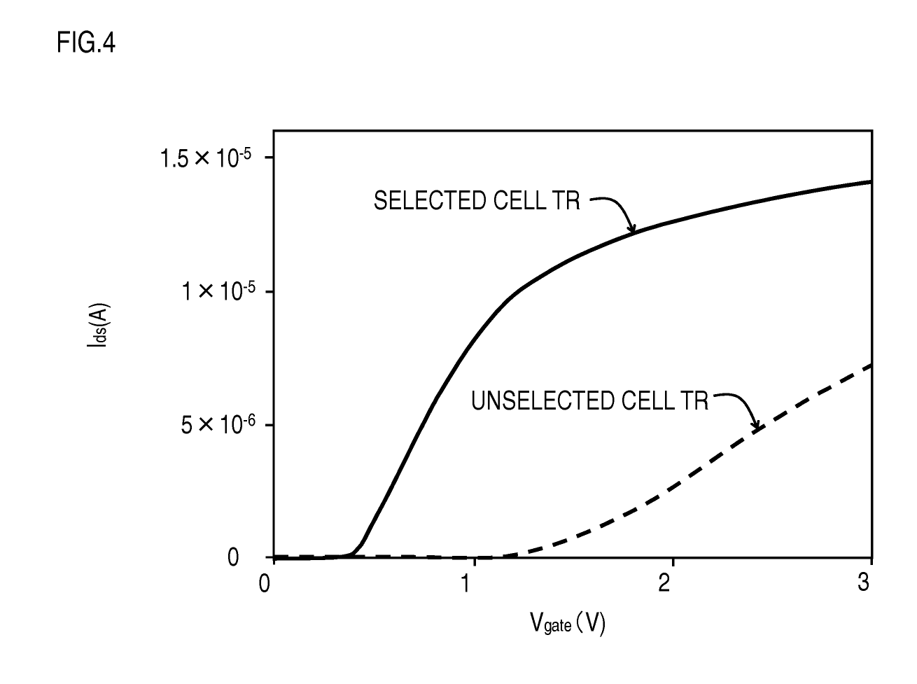

Next, a description is given concerning operation of a memory cell in the semiconductor device according to the first exemplary embodiment of the present disclosure, with reference to the drawings. FIG. 4 is a current/voltage characteristic diagram of a selected cell transistor and an unselected cell transistor for describing operation of the memory cell in the semiconductor device according to the first exemplary embodiment of the disclosure.

With regard to the memory cell as shown in FIG. 1, a current voltage characteristic simulation was made on the selected cell transistor and the unselected cell transistor, with parameters and voltage conditions as set below.

With the parameters and voltage conditions as shown below, ideally a current does not flow in the unselected cell transistor, but the present disclosure is not limited thereto. That is, even in a case where a current flows in the unselected cell transistor, a range is allowed in which a resistance variation does not occur in the variable resistance element 14 due to the current.

Parameters

technology node=40 nm

cell size=0.0064 μm

impurity concentration of p-type body region 1c=1×10¹⁶ cm⁻³

impurity concentration of n-type diffusion regions 1b and 1d=1×10²⁰ cm⁻³

thickness of gate insulating film 8=5 nm

distance from bottom of groove 6 to word line 9=30 nm

height of pillar 2=150 nm

width in direction of extension of word line 9 of pillar 2=30 nm

width in direction of extension of bit line 15 of pillar 2=10 nm

Voltage Conditions

WL1 voltage V_{WL1} (V_{gate})=0->3V

WL2 voltage V_{WL2} (V_{gate})=0->3V

WL3 voltage V_{WL3}=−1V (constant)

source voltage V_{source}=0V

BL2 voltage V_{BL2}=2V

In a case of operating a memory cell under the voltage conditions shown above, a characteristic diagram of source-drain current I_{ds} and gate voltage V_{gate} of the selected cell transistor and the unselected cell transistor respectively is shown in FIG. 4. In a case where V_{gate}=1V, a current flows in the selected cell transistor, but a current does not flow in the unselected cell transistor since a negative bias is applied to the opposing WL3. In this way, in the three dimensional transistor, by operating with a negative bias in the opposing gate (word line) of the unselected cell transistor adjacent to the selected cell transistor, separation of WL2, which has generally been necessary, becomes unnecessary.

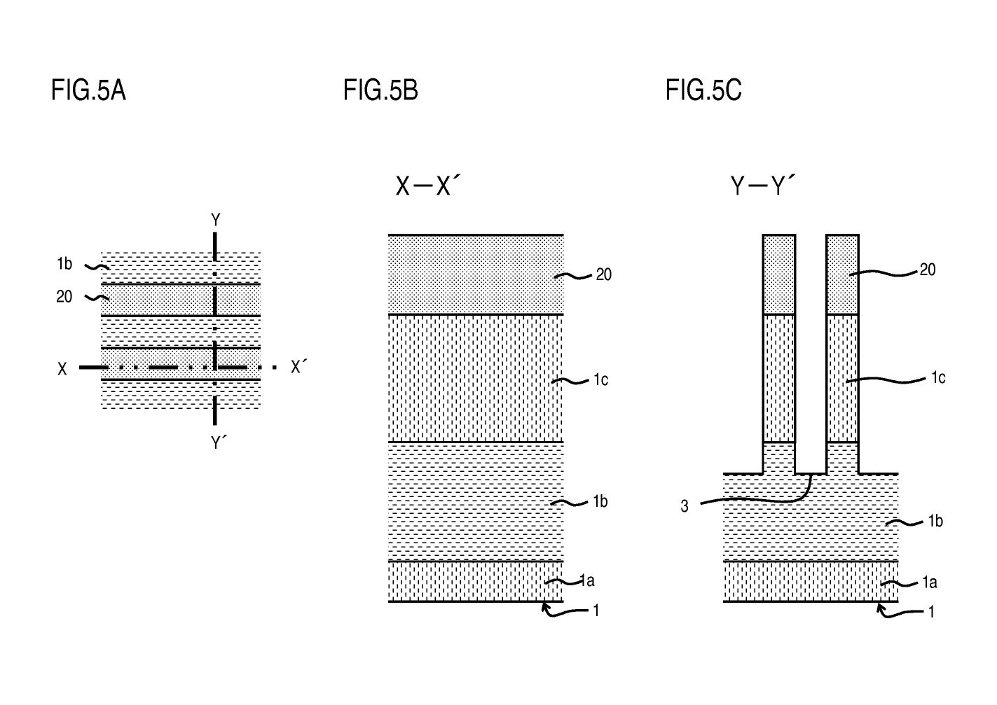

Next, a description is given concerning a method of manufacturing the semiconductor device according to the first exemplary embodiment of the present disclosure, making use of the drawings. FIGS. 5A to FIG. 17C show (A) a plan view, (B) a cross sectional view at X-X′, and (C) a cross sectional view at Y-Y′, for describing the method of manufacturing the semiconductor device according to the first exemplary embodiment of the disclosure.

First, a semiconductor substrate 1 is prepared, in which the p-type diffusion region 1a, the n-type diffusion region 1b, and the p-type body region 1c are stacked from the bottom; a silicon nitride film 20 (with a film thickness of the order of 200 nm, for example) is disposed on the p-type body region 1c; and thereafter a groove(s) 3 (for example, with an inter-groove(s) gap of the order of 40 nm, a groove width of the order of 40 nm, and a depth of the order of 200 nm) is(are) formed by lithography and etching (step A1; see FIGS. 5A, 5B and 5C).

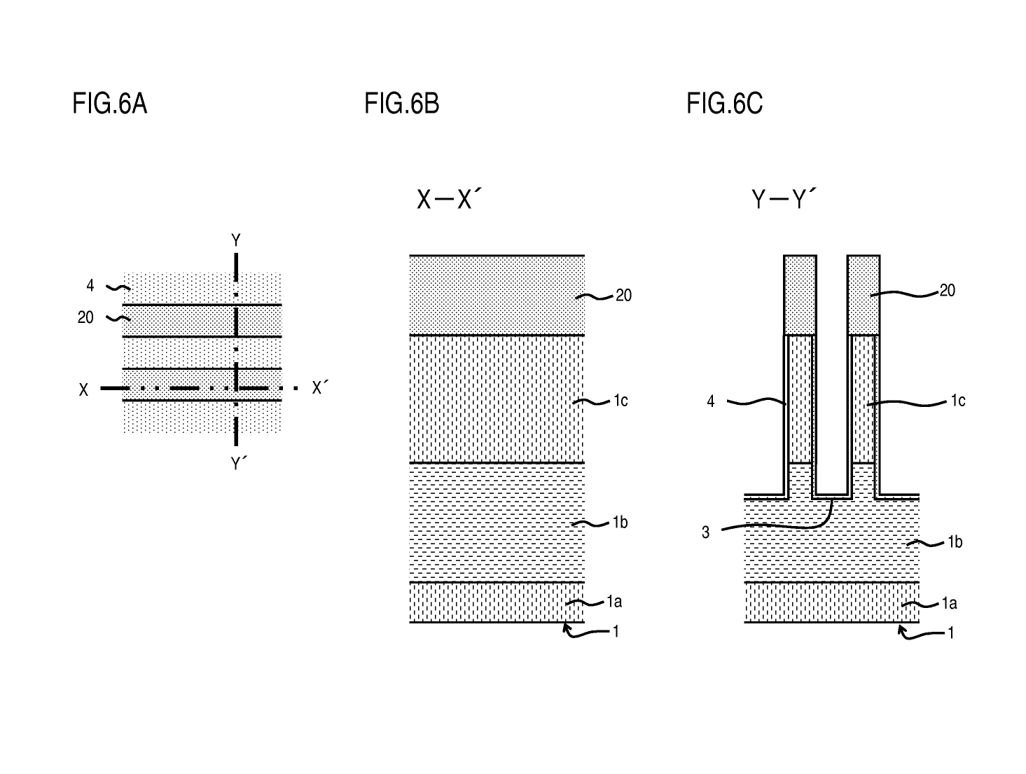

Next, the insulating film 4 (with a film thickness of the order of nm) is formed on a surface of the n-type diffusion region 1b and the p-type body region 1c, both exposed in the groove 3 by oxidation (for example, thermal oxidation) (step A2; see FIGS. 6A, 6B and 6C).

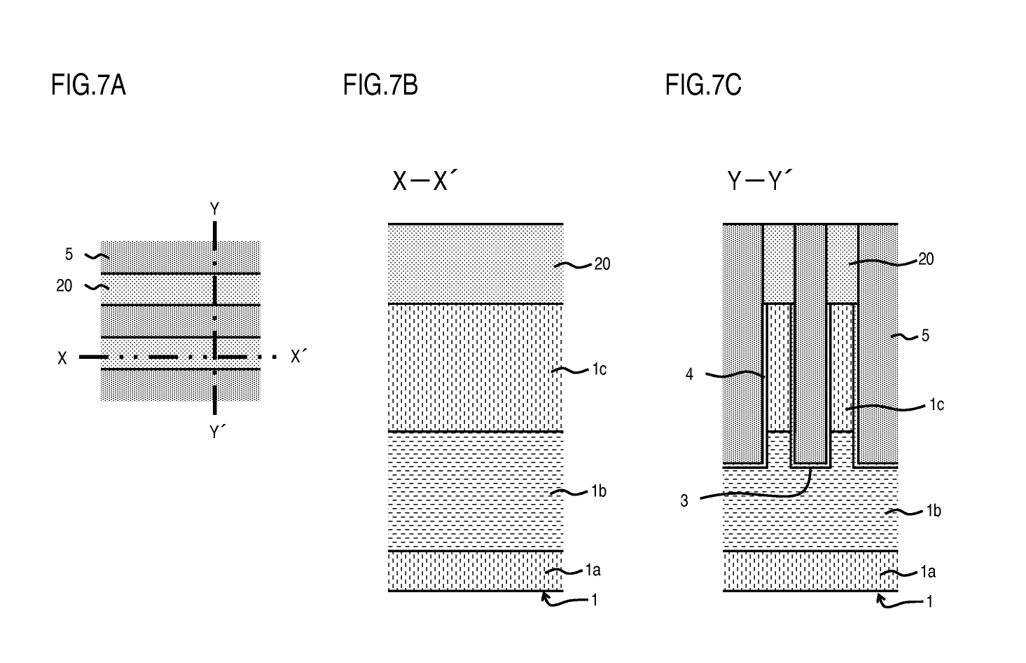

Next, the interlayer insulating film 5 (for example, a silicon nitride film) is formed on the whole substrate by CVD (Chemical Vapor Deposition), and thereafter the interlayer insulating film 5 is polished (flattened) until the silicon nitride film 20 appears, by CMP (Chemical Mechanical Polishing) (step A3; see FIGS. 7A, 7B and 7C).

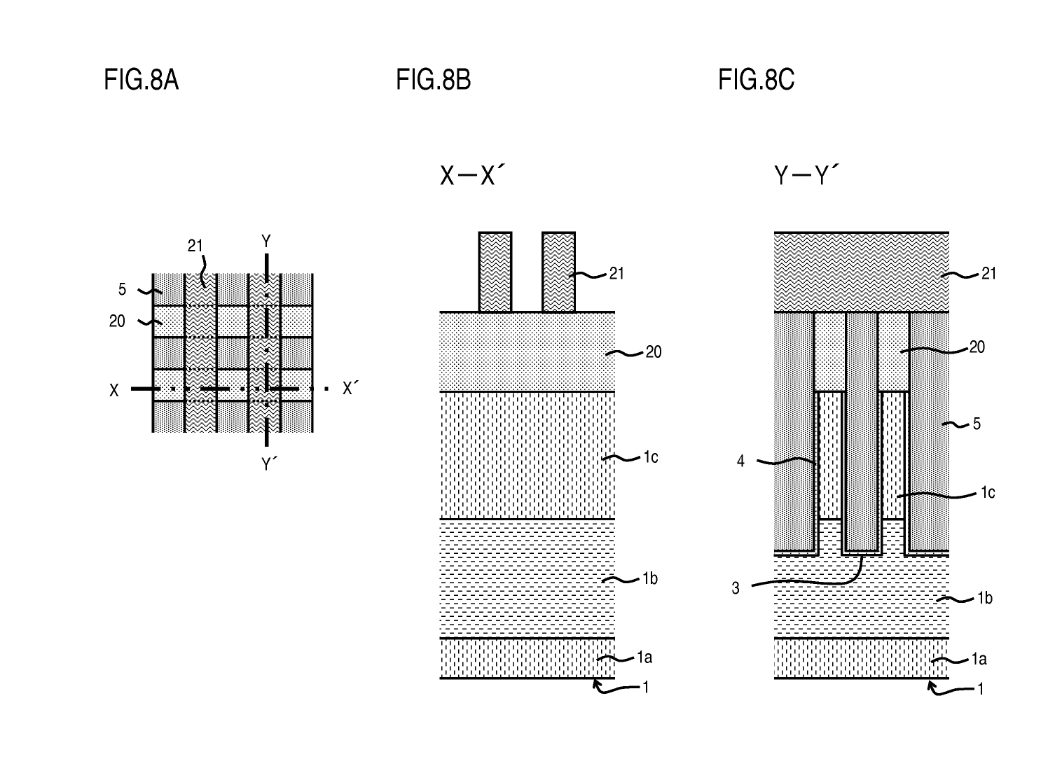

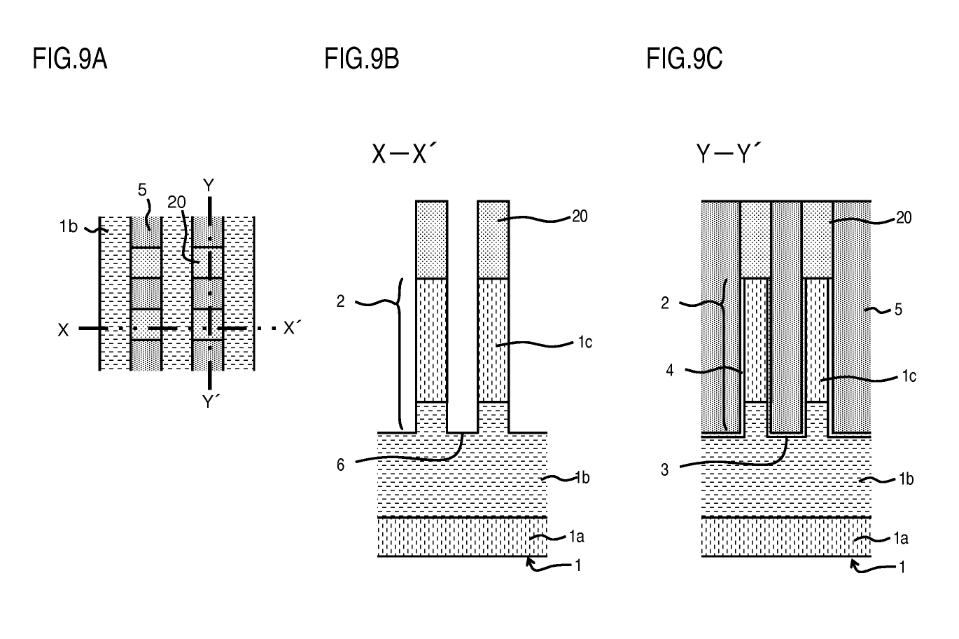

Next, a photoresist 21 is formed for making a groove at a prescribed position(s) on the interlayer insulating film 5 including the silicon nitride film 20 (step A4; see FIGS. 8A, 9B and 9C).

Next, the groove 3 and the groove 6 with a depth of the same order (for example, an inter-groove gap of the order of 40 nm, a groove width of the order of 40 nm, and a depth of the order of 200 nm) are formed by etching the silicon nitride film 20 and the interlayer insulating film 5, with the photoresist (21 in FIGS. 8A, 9B and 9C) as a mask, and thereafter removing the photoresist (21 in FIGS. 8A, 9B and 9C) (step A5; see FIGS. 9A, 9B and 9C).

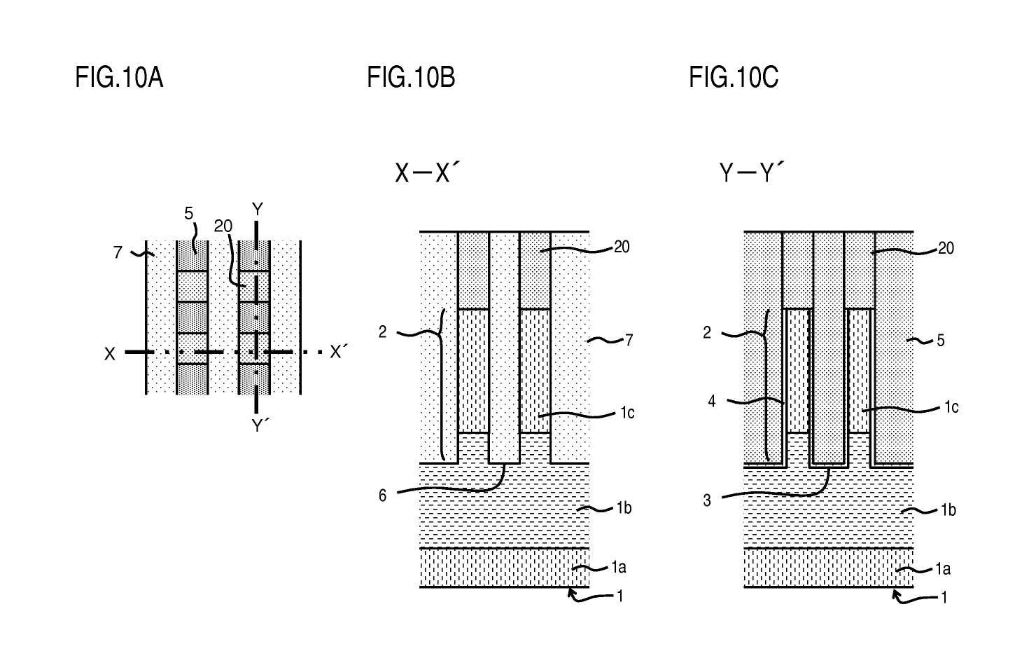

Next, the interlayer insulating film 7 (for example, a silicon nitride film) is formed on the whole surface of the substrate, and thereafter the interlayer insulating film 7 is polished (flattened) until the silicon nitride film 20 appears, by CMP (step A6; see FIGS. 10A, 10B and 10C).

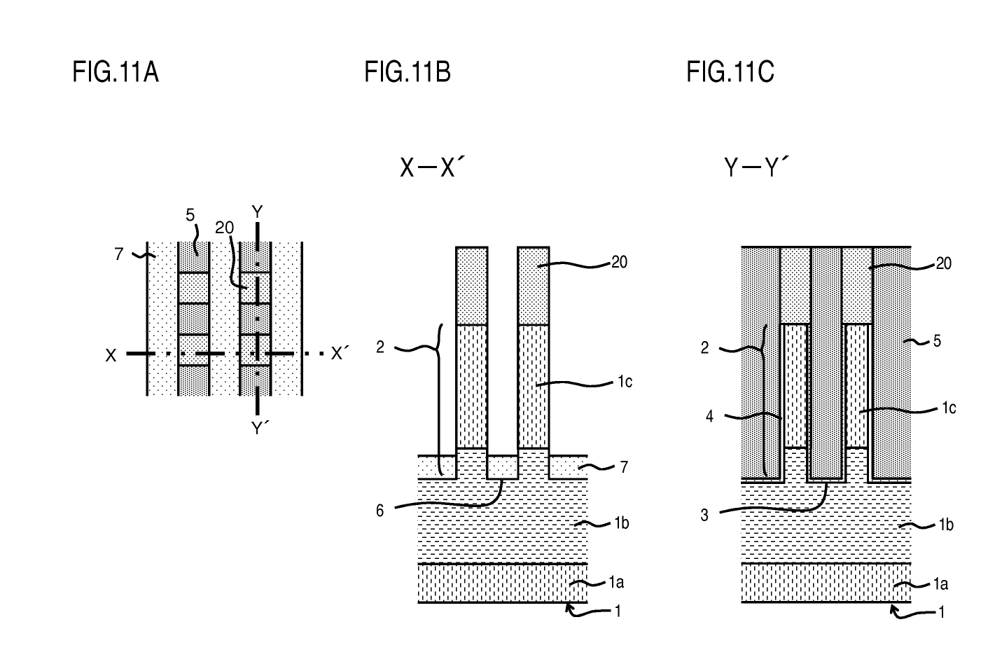

Next, the interlayer insulating film 7 is selectively etched until the upper surface of the interlayer insulating film 7 is lower than a boundary face of the n-type diffusion region 1b and the p-type body region 1c (step A7; see FIGS. 11A, 11B and 11C).

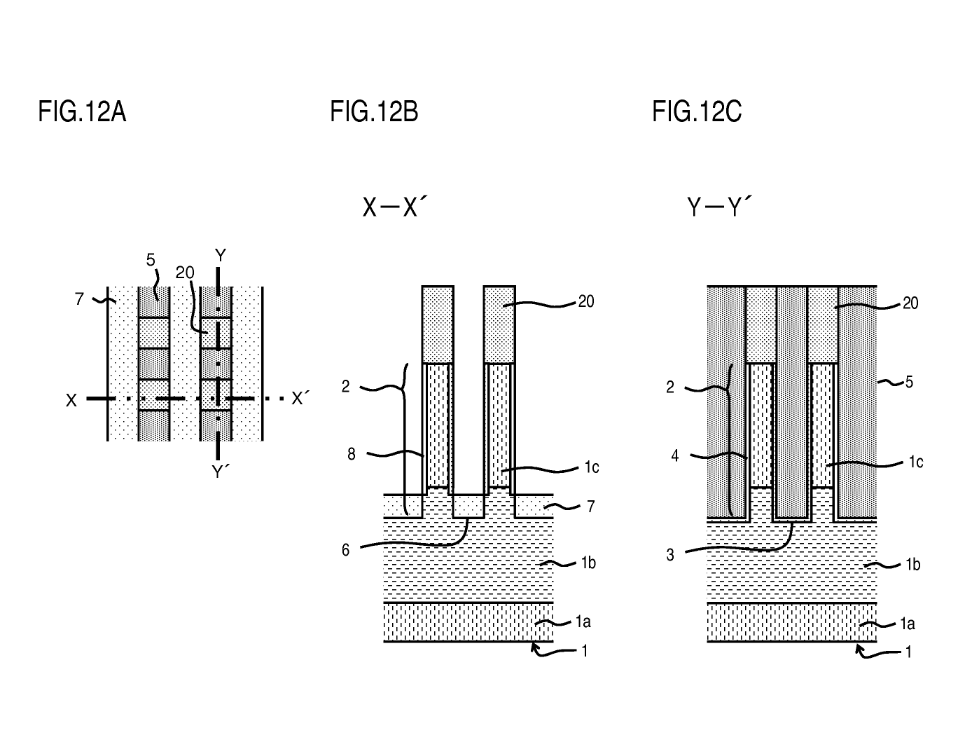

Next, the gate insulating film 8 (with a film thickness of the order of 5 nm) is formed on a surface of the n-type diffusion region 1b and the p-type body region 1c, exposed at a portion above the interlayer insulating film 7 of the groove 3 by oxidation (for example, thermal oxidation) (step A8; see FIGS. 12A, 12B and 12C).

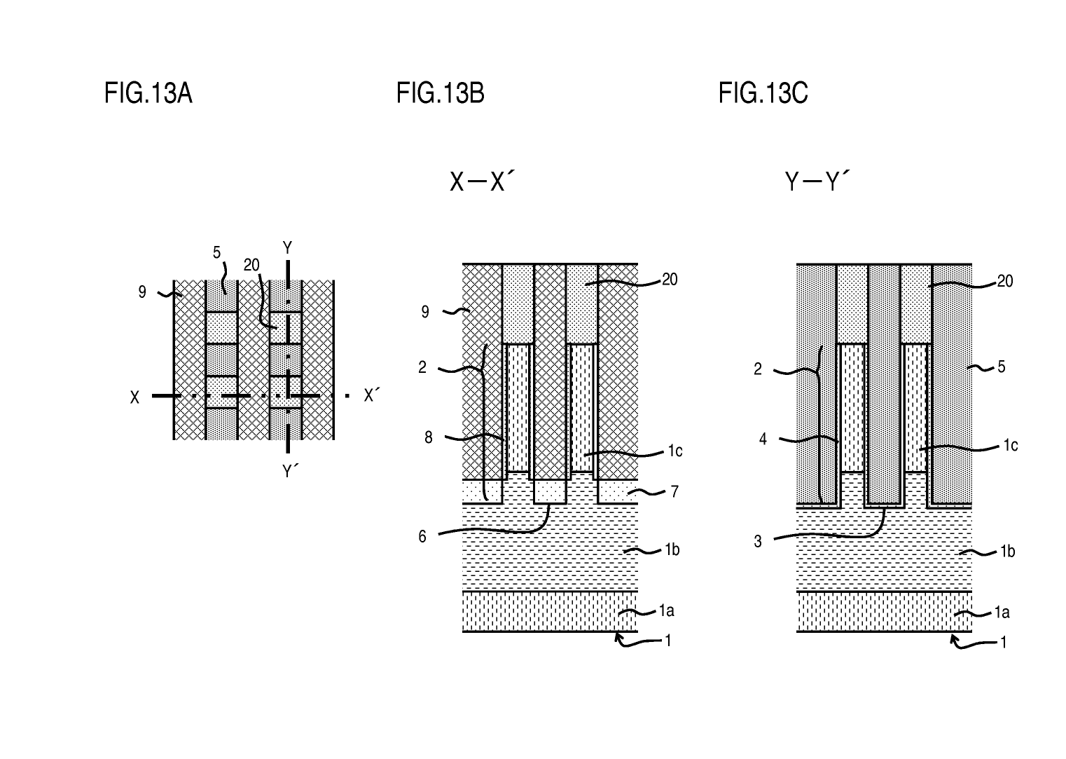

Next, a conductive film 9 for a word line is formed on the whole surface of the substrate by CVD, and thereafter the conductive film 9 is polished (flattened) until the silicon nitride film 20 appears, by CMP (step A9; see FIGS. 13A, 13B and 13C).

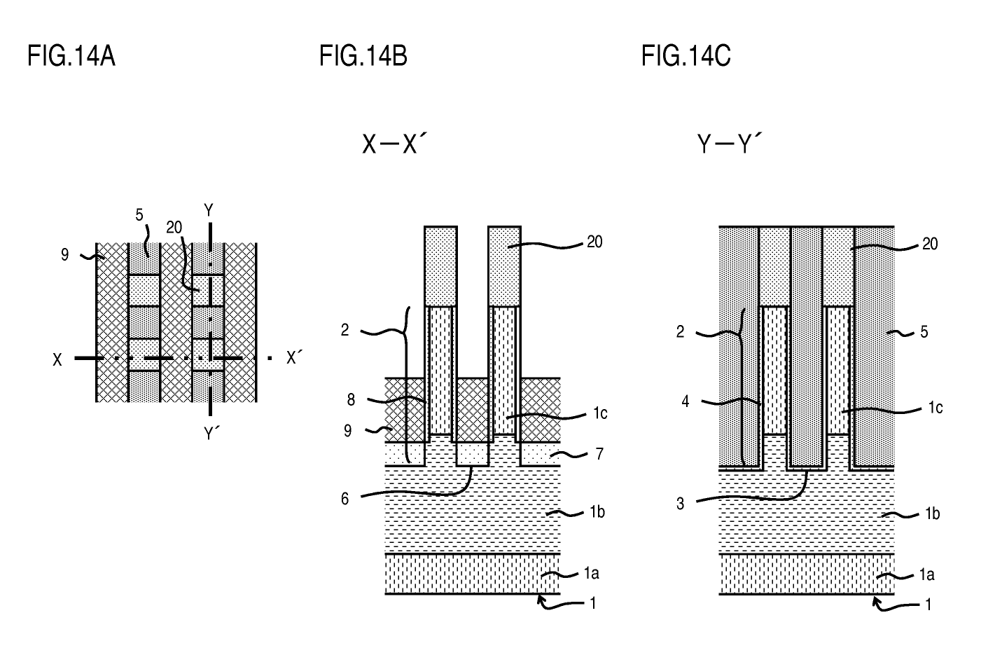

Next, the word line 9 originating from the conductive film (9 in FIGS. 13A, 13B and 13C) is formed by selectively etching the conductive film (9 in FIGS. 13A, 13B and 13C) until the upper surface of the conductive film (9 in FIGS. 13A, 13B and 13C) is of the order of half the height of the p-type body region 1c (step A10; see FIGS. 14A, 14B and 14C). It is to be noted that the word line 9 does not require separation between adjacent cells.

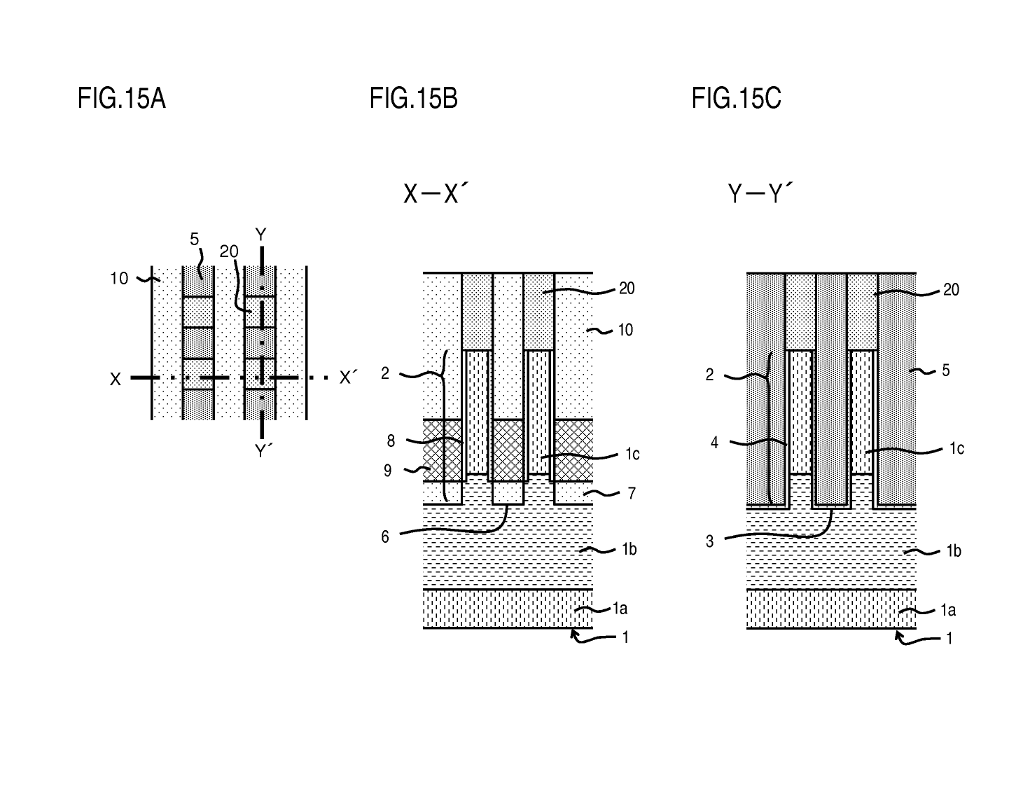

Next, the interlayer insulating film 10 is formed on the whole surface of the substrate by CVD, and thereafter the interlayer insulating film 10 is polished (flattened) until the silicon nitride film 20 appears, by CMP (step A11; see FIGS. 15A, 15B and 15C).

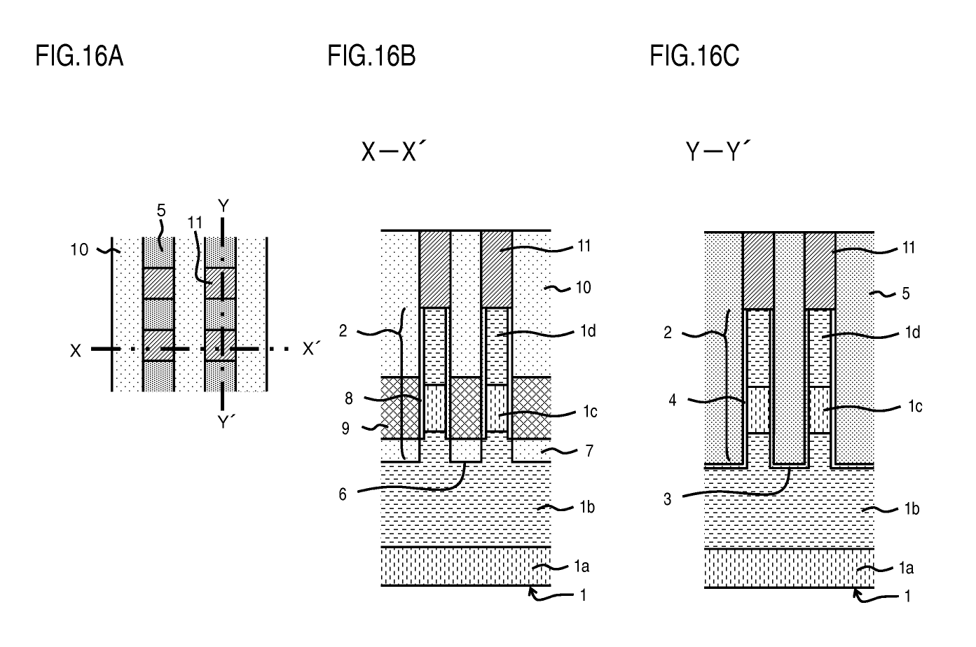

Next, etching removal of the silicon nitride film 20 is performed by lithography and etching until the p-type body region 1c appears; thereafter the n-type diffusion region 1d, which is a drain, is formed by injecting n-type impurities into the p-type body region 1c; thereafter a conductive film for the contact plug 11 is formed by CVD on the whole surface of the substrate; and thereafter the contact plug 11 is formed by polishing (flattening) the conductive film in question until the interlayer insulating films 5 and 10 appear, by CMP (step A12; FIGS. 16A, 16B and 16C). It is to be noted that with regard to the form of the n-type diffusion region 1d, the n-type impurities are injected into the p-type body region 1c, so that the boundary face of the n-type diffusion region 1d and the p-type body region 1c is about the same or lower than the upper surface of the word line 9.

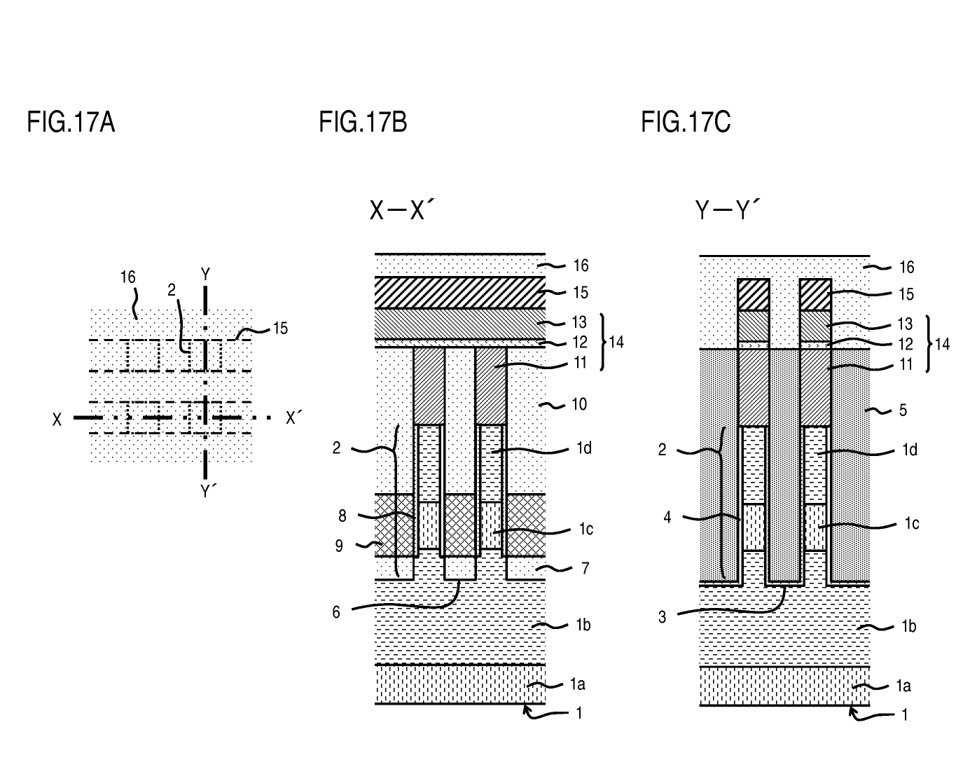

Next, a conductive film for the variable resistance film 12 and the upper electrode film 13, and a conductive film (W, etc.) for the bit line 15 are formed in this order on the whole surface of the substrate; thereafter the variable resistance film 12, the upper electrode film 13, and the bit line 15 are made in a line form by lithography and etching; and thereafter the interlayer insulating film 16 is formed by CVD on the whole surface of the substrate (step A13; see FIGS. 17A, 17B and 17C). Thereafter the method continues with a typical wiring manufacturing process.

According to the first exemplary embodiment, since word line separation between adjacent cells by etching is unnecessary, processing steps are facilitated even where the gap between transistors is further narrowed.

### Second Exemplary Embodiment

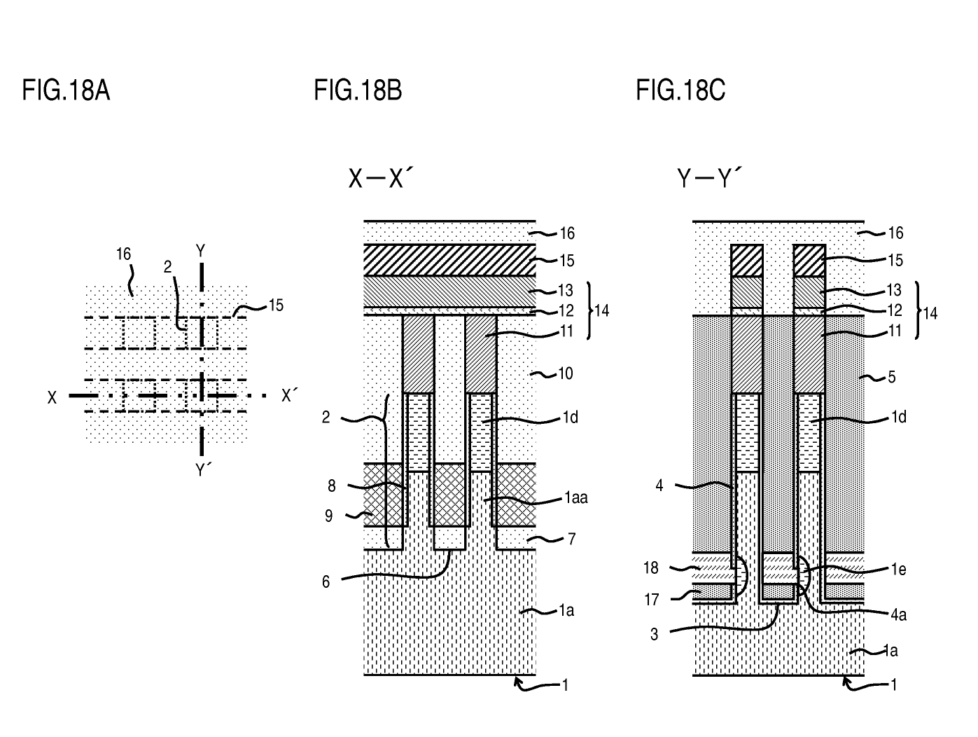

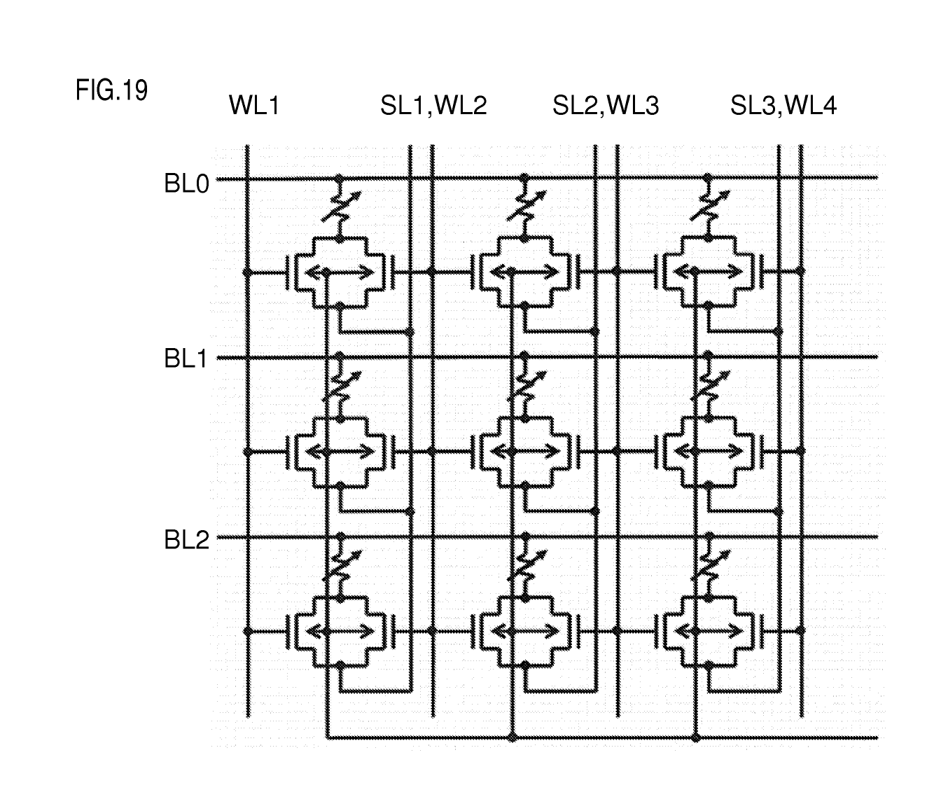

A description is given concerning a semiconductor device according to a second exemplary embodiment of the present disclosure, making use of the drawings. FIG. 18A is a plan view, FIG. 18B is a cross sectional view at X-X′, and FIG. 18C is a cross sectional view at Y-Y′, schematically showing a configuration of the semiconductor device according to the second exemplary embodiment of the disclosure. FIG. 19 is a circuit diagram schematically showing a configuration of a memory cell array in the semiconductor device according to the second exemplary embodiment of the present disclosure.

The second exemplary embodiment is a modified example of the first exemplary embodiment: a p-type body region (equivalent to 1c in FIG. 1) is no longer floated with respect to a base of a semiconductor substrate 1, an n-type diffusion region (1b in FIG. 2) is no longer provided in the semiconductor substrate 1, and a p-type body region 1aa forming part of a pillar 2 is integrated with a p-type diffusion region 1a that forms the base (see FIGS. 18A, 18B and 18C). A groove 3 is formed to be deeper than a groove 6. Accompanying this, a doped silicon film 18 forming a source line (corresponding to SL1 to SL3 in FIG. 19) is provided between an interlayer insulating film 17 and an interlayer insulating film 5 in the groove 3; a hole 4a is provided in an insulating film 4, and an n-type diffusion region 1e electrically connected to the doped silicon film 18 through the hole 4a is provided in a p-type diffusion region 1a (see FIGS. 18A, 18B and 18C). The doped silicon film 18 is arranged at a position deeper than a word line 9 so as not to have contact with the word line 9. The doped silicon film 18 extends in a direction orthogonal to a direction of extension of the word line 9. Since each p-type body region 1aa is integral with the p-type diffusion region 1a, the electrical potential is the same (see FIGS. 18A, 18B and 18C and FIG. 19). The configuration is otherwise the same as the first exemplary embodiment.

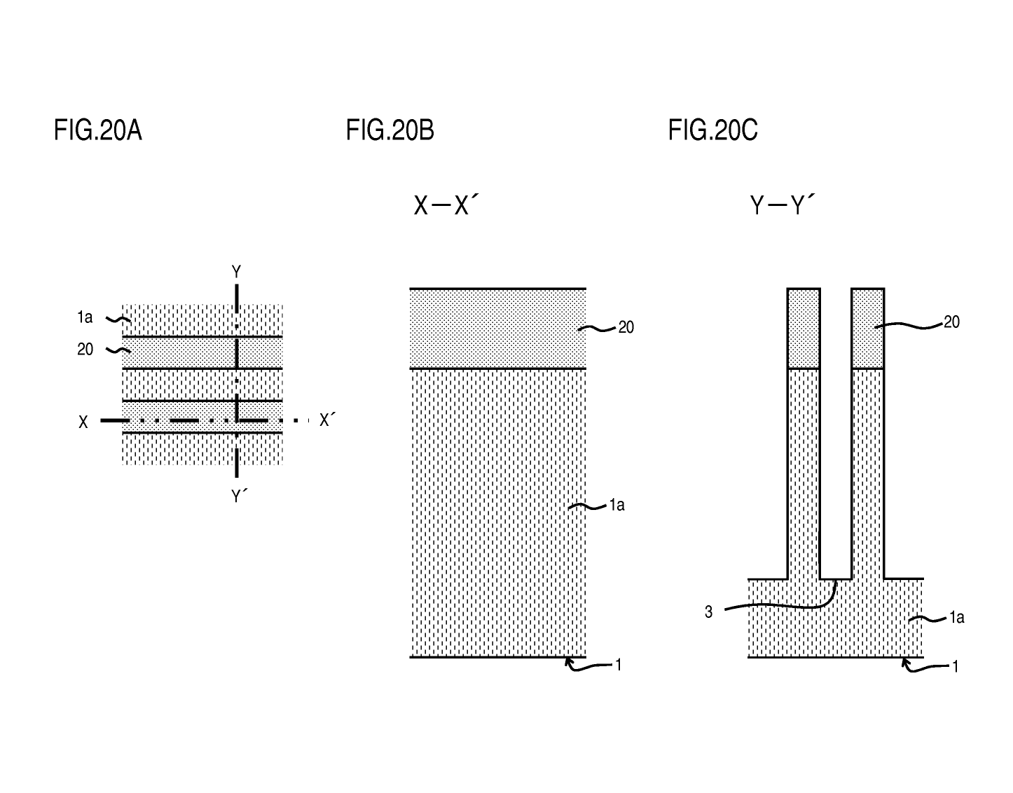

Next, a description is given concerning a method of manufacturing the semiconductor device according to the second exemplary embodiment of the present disclosure, making use of the drawings. FIG. 20A to FIG. 28C show (A) a plan view, (B) a cross sectional view at X-X′, and (C) a cross sectional view at Y-Y′, for describing the method of manufacturing the semiconductor device according to the second exemplary embodiment of the disclosure.

First, from the bottom, the semiconductor substrate 1 formed from the p-type diffusion region 1a is provided; a silicon nitride film 20 (with a film thickness of the order of 200 nm, for example) is formed on the p-type diffusion region 1a; and thereafter the groove 3 (a groove deeper than the groove 3 in FIGS. 5A, 5B and 5C according to the first exemplary embodiment) is formed by lithography and etching (step B1; see FIGS. 20A, 20B and 20C).

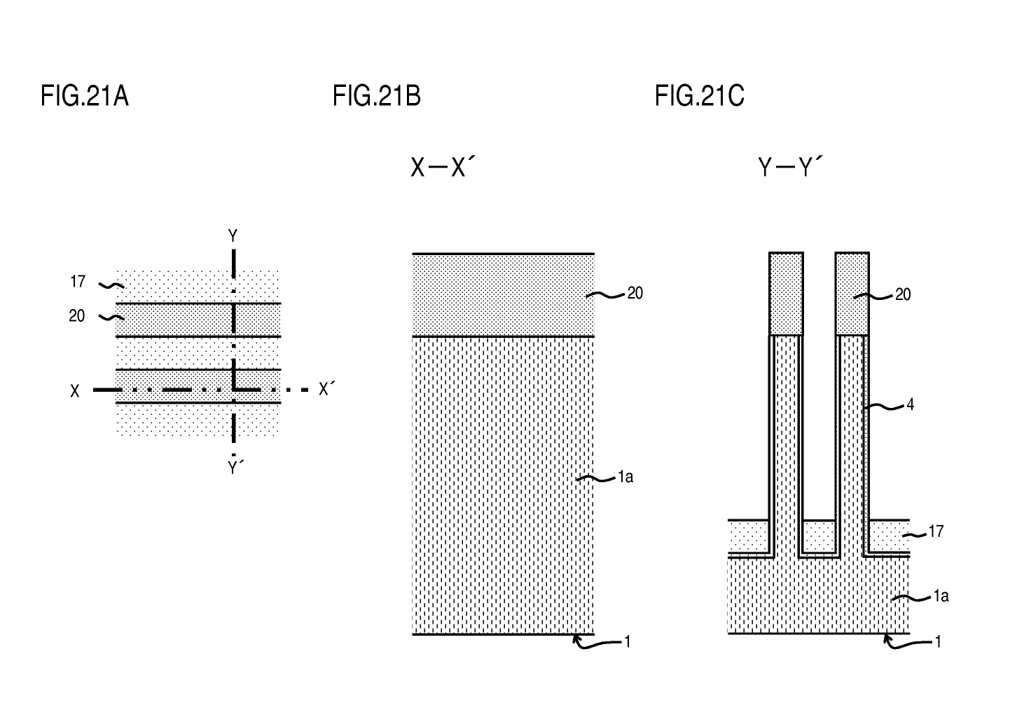

Next, an insulating film 4 (with a film thickness of the order of 5 nm) is formed on a surface of the p-type diffusion region 1a exposed in the grove 3 by oxidation (for example, thermal oxidation); thereafter an interlayer insulating film 17 is formed on the whole substrate by CVD; thereafter the interlayer insulating film 17 is polished (flattened) until the silicon nitride film 20 appears, by CMP; and thereafter the interlayer insulating film 17 is selectively etched until the interlayer insulating film 17 has a prescribed thickness (step B2; see FIG. 21).

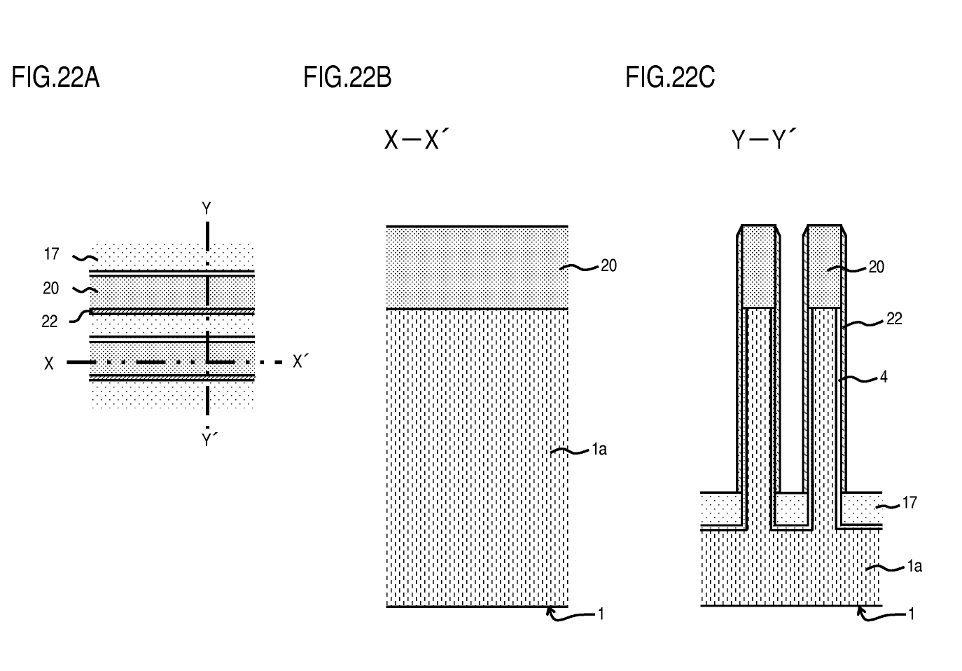

Next, an insulating film (for example, a silicon nitride film) for a side wall 22 is formed on the whole substrate by CVD; and thereafter the sidewall 22 is formed on a wall face inside the groove 3 (side wall face of the silicon nitride film 20 and the insulating film 4, that are exposed) by etching (step B3; see FIGS. 22A, 22B and 22C).

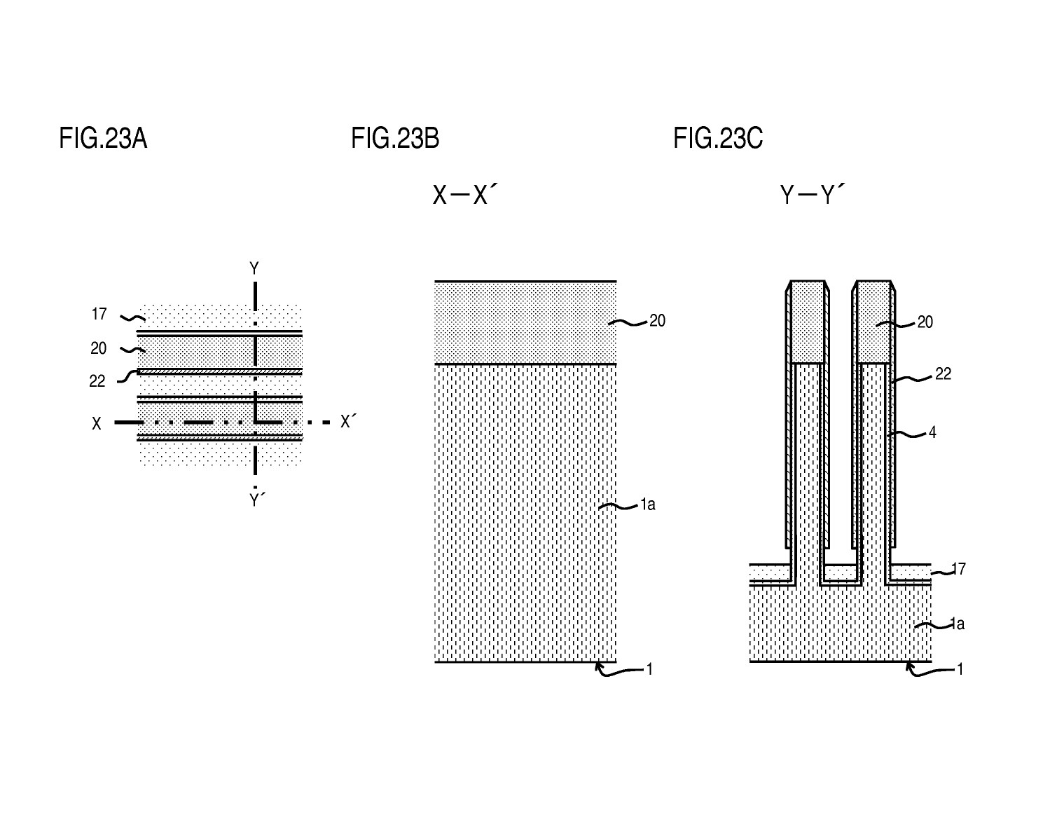

Next, the interlayer insulating film 17 is selectively etched until the interlayer insulating film 17 has a prescribed thickness (thinner than in step B2), with the silicon nitride film 20 and the sidewall 22 as a mask (step B4; see FIGS. 23A, 23B and 23C). In this way, a part of the insulating film 4 is exposed at a position defined between the sidewall 22 and the interlayer insulating film 17.

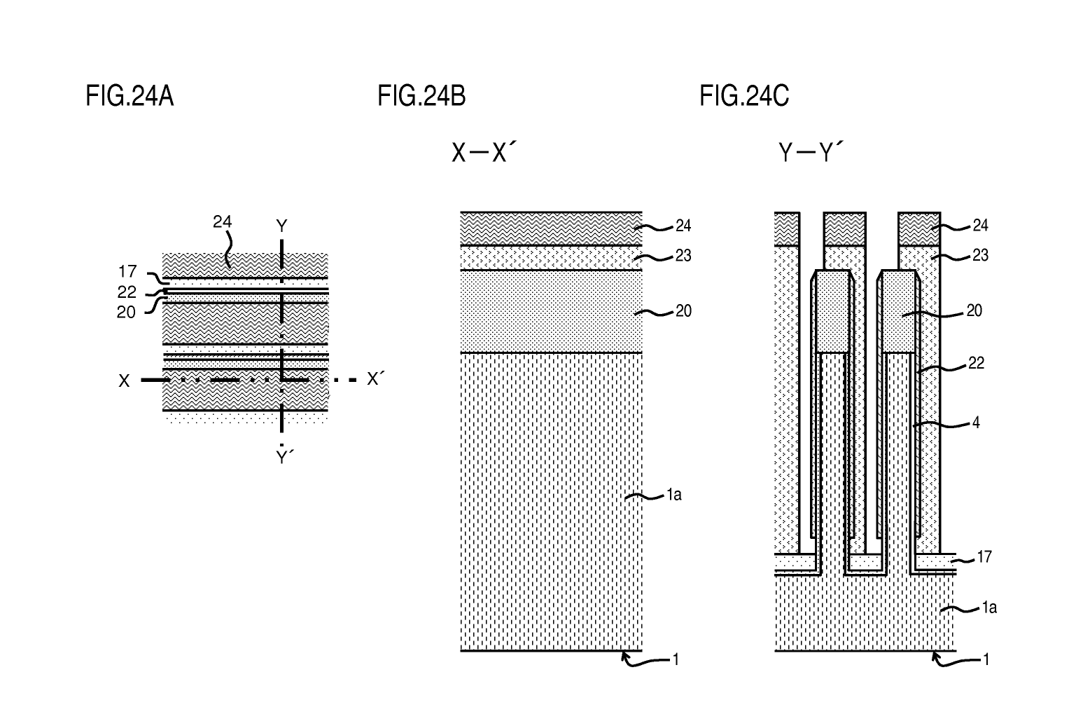

Next, an interlayer insulating film 23 is formed on the whole substrate by CVD; thereafter the interlayer insulating film 23 is polished (flattened) to an extent such that the silicon nitride film 20 does not appear, by CMP; thereafter a photoresist 24 for forming a hole (4a in FIGS. 18A, 18B and 18C) is formed at a prescribed position in the interlayer insulating film 23; and thereafter the interlayer insulating film 23 is selectively etched until the interlayer insulating film 17 and the insulating film 4 appear (step B5; see FIGS. 24A, 24B and 24C).

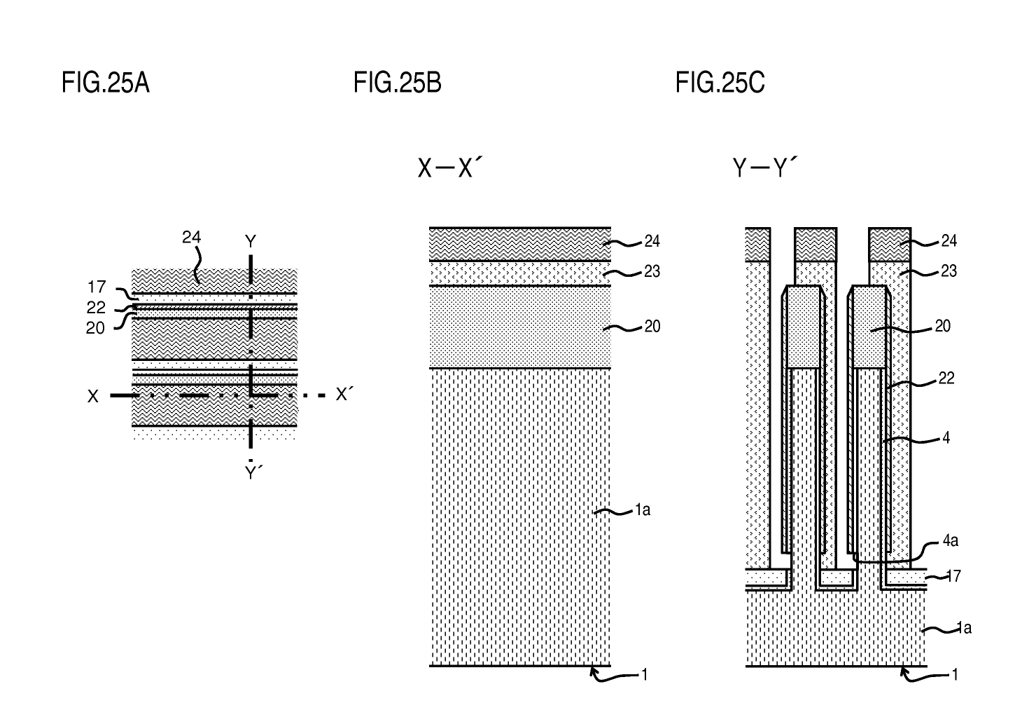

Next, with the photoresist 24, the interlayer insulating film 23, the silicon nitride film 20, the sidewall 22, and the interlayer insulating film 17 as a mask, selective etching removal is performed on the insulating film 4 until the p-type diffusion region 1a appears (step B6; see FIGS. 25A, 25B and 25C).

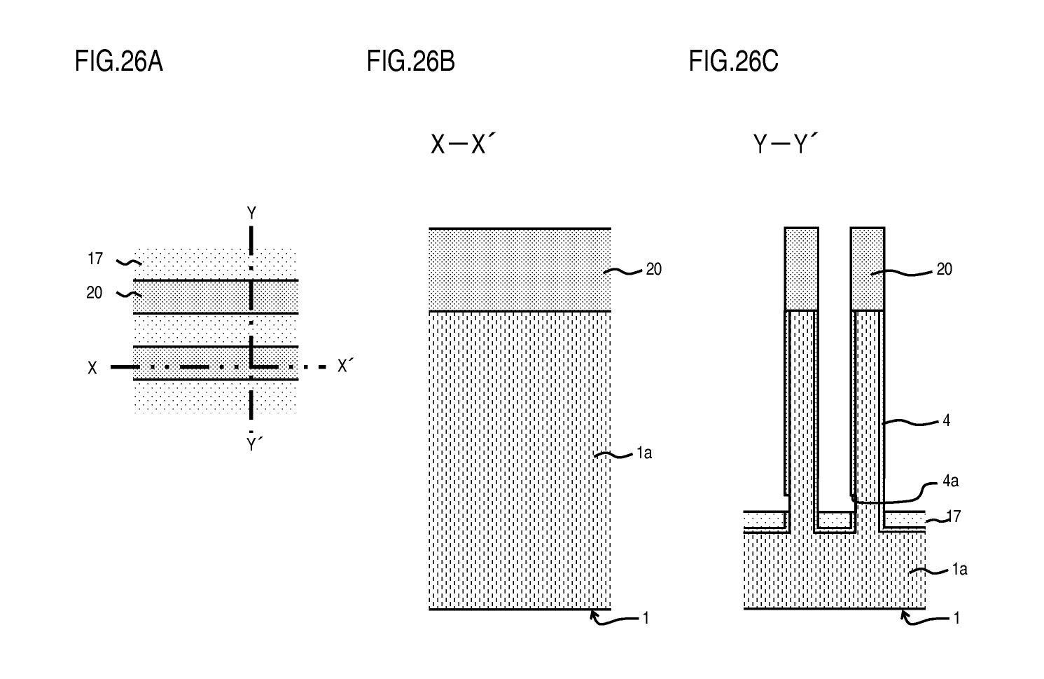

Next, the photoresist (24 in FIGS. 25A, 25B and 25C), the interlayer insulating film (23 in FIGS. 25A, 25B and 25C), and the sidewall (22 in FIGS. 25A, 25B and 25C) are removed (step B7; see FIGS. 26A, 26B and 26C).

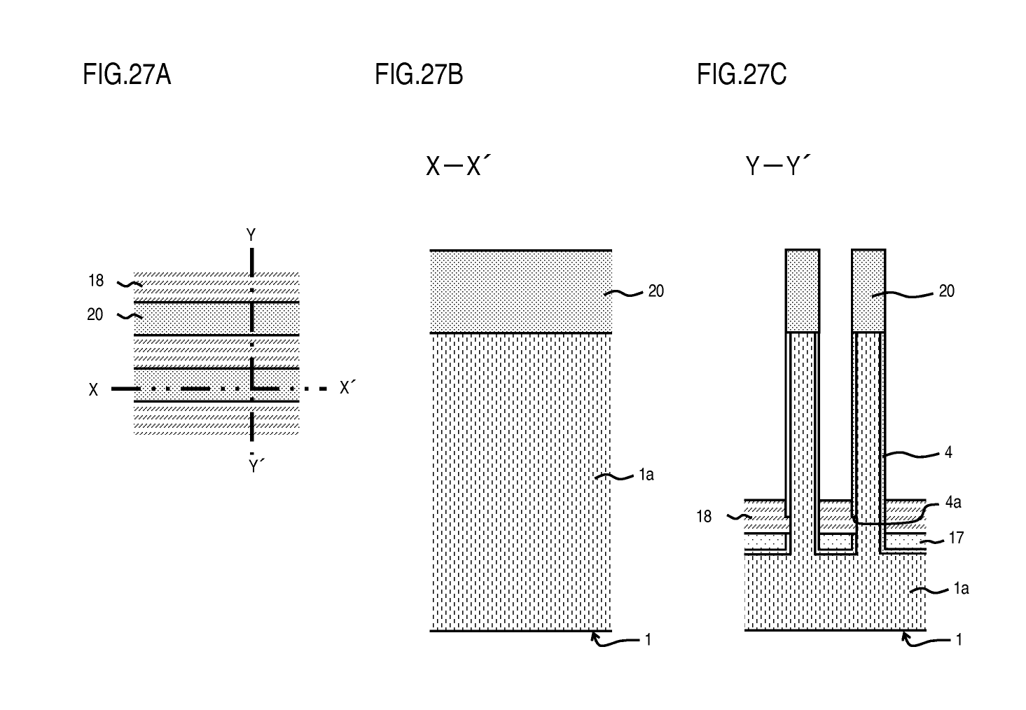

Next, the doped silicon film 18 for a source line is formed on the whole substrate; thereafter the doped silicon film 18 is polished (flattened) until the silicon nitride film 20 appears, by CMP; and thereafter the doped silicon film 18 is selectively etched until the doped silicon film 18 has a prescribed thickness (step B8; see FIGS. 27A, 27B and 27C).

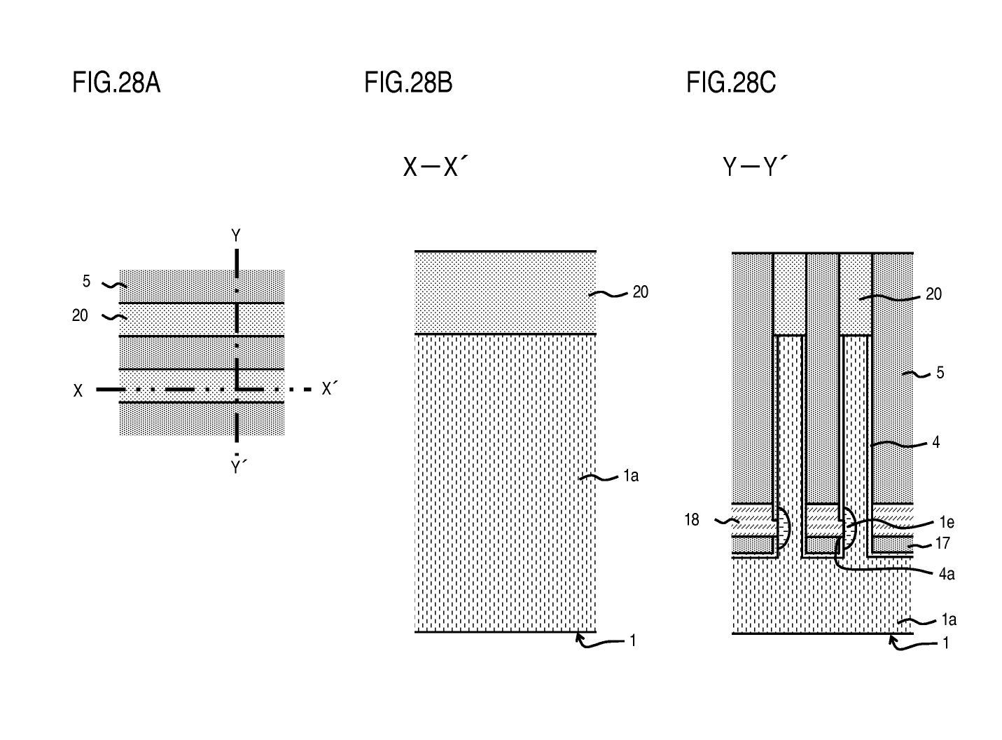

Next, an interlayer insulating film 5 is formed on the whole surface of the substrate; and thereafter the interlayer insulating film 5 is polished (flattened) until the silicon nitride film 20 appears, by CMP (step B9; see FIG. 28).

Thereafter, by performing steps similar to steps A4 to A13 (see FIG. 8A to FIG. 17C) of the first exemplary embodiment, a memory cell as in FIGS. 18A, 18B and 18C can be obtained.

According to the second exemplary embodiment, an effect similar to that of the first exemplary embodiment is realized, and it is possible to make relatively stable a current to flow in the variable resistance element 14, by a stable electrical potential of the p-type body region 1aa.

It is to be noted that, as an example similar to the three-dimensional transistor of longitudinal structure type, Non-Patent Literature 1 discloses a semiconductor device that uses a floating body memory cell which operates memory according to a stored charge state in a body region to which a constant potential is not supplied. A three dimensional transistor described in Non-Patent Literature 1 has a configuration where a storage element part is shared with a three dimensional transistor, and wiring between memory cells is not separated, so that a memory cell program is controlled by two word lines sandwiching the floating body memory cell. However, Non-Patent Literature 1 merely describes control of the floating body memory cell, and has a structure that differs from the disclosure of the present application where the storage element part is formed in an upper part of the three dimensional transistor.

Where reference symbols are attached to the drawings in the present application, these are solely to aid understanding and are not intended to limit the disclosure to modes illustrated in the drawings.

Modifications and adjustments of exemplary embodiments and examples are possible within the bounds of the entire disclosure (including the scope of the claims and drawings) of the present invention, and also based on fundamental technological concepts thereof. Furthermore, various combinations and selections of various disclosed elements (including respective elements of the respective claims, respective elements of the respective exemplary embodiments and examples, and respective elements of the respective drawings) are possible within the scope of the claims of the present invention. That is, the present invention clearly includes every type of transformation and modification that a person skilled in the art can realize according to the entire disclosure including the scope of the claims drawings, and to technological concepts thereof.

What is claimed is:

1. A semiconductor device comprising:
a first transistor including a first diffusion region of a first conductivity type, a first body region of a second conductivity type and a second diffusion region of the first conductivity type, the first and second diffusion regions and the first body region being arranged in a direction orthogonal to a main surface;
a second transistor including a third diffusion region of the first conductivity type, a second body region of the second conductivity type and a fourth diffusion region of the first conductivity type, the third and fourth diffusion regions and the second body region being arranged in the direction orthogonal to the main surface;
a first variable resistance element provided on the second diffusion region of the first transistor;
a second variable resistance element provided on the fourth diffusion region of the second transistor;
a bit line commonly connected to the first variable resistance element and the second variable resistance element;
a first word line arranged on a first side of the first body region;
a second word line arranged between a second side of the first body region and a first side of the second body region; and
a third word line arranged on a second side of the second body region.

2. The semiconductor device according to claim 1, wherein the first word line, the second word line and the third word line are electrically independent from each other.

3. The semiconductor device according to claim 1, wherein the first body region and the second body region are floating with respect to a base of a semiconductor substrate.

4. The semiconductor device according to claim 1, comprising:
a first source line and a second source line arranged at a position that is deeper than the first word line and the second word line; wherein
the first body region and the second body region are integral with respect to the base of the semiconductor substrate;
the first diffusion region is electrically connected to the first source line; and
the second diffusion region is electrically connected to the second source line.

5. The semiconductor device according to claim 4, wherein the first source line and the second source line extend in a direction orthogonal to a direction in which the first word line and the second word line extend.

6. A method of manufacturing a semiconductor device, comprising:
forming a plurality of pillars by forming a groove, in a semiconductor substrate having at least, in a first diffusion region of a first conduction type, a body region of a second conduction type, the groove being deeper than a boundary face of the first diffusion region and the body region;
forming an interlayer insulating film whose upper face is lower than the boundary face of the first diffusion region and the body region, on the body region between the pillars;
forming a gate insulating film on a sidewall face of the pillars at a position higher than the upper face of the interlayer insulating film;
forming a word line whose upper face is lower than an upper face of the pillars, on the interlayer insulating film between the gate insulating films;
forming a second diffusion region of the first conduction type by injecting impurities from an upper face side into the body region of the pillars; and
forming a variable resistance element in the second diffusion region.

7. A device comprising:
a substrate including a main surface;
first, second and third diffusion regions arranged in line in a direction perpendicular to the main surface, the first and third diffusion regions being the same in conductivity type as each other, the second diffusion region being different in conductivity type from each of the first and third diffusion regions, and being sandwiched between the first and third diffusion regions;
fourth, fifth and sixth diffusion regions arranged in line in the direction perpendicular to the main surface, the fourth and sixth diffusion regions being the same in conductivity type as each other, the fifth diffusion region being different in conductivity type from each of the fourth and sixth diffusion regions, and being sandwiched between the fourth and sixth diffusion regions;
first, second and third wirings each elongating in a direction in parallel to the main surface, the first and second wirings sandwiching the second diffusion region therebetween with an intervention of an insulating film, the second and third wirings sandwiching the fifth diffusion region therebetween with an intervention of an insulating film.

8. The device according to claim 7, wherein there is no wiring between the first and third wirings except for the second wiring.

9. The device according to claim 7, wherein the first and third diffusion regions are formed as source and drain of a first transistor, the second diffusion region being formed as a body of the first transistor, each of the first and second wirings being formed as a gate of the first transistor.

10. The device according to claim 9, wherein the fourth and sixth diffusion regions are formed as source and drain of a second transistor, the fifth diffusion region being formed as a body of the second transistor, each of the third and second wirings being formed as a gate of the second transistor.

11. The device according to claim 7, further comprising a first memory element on the third diffusion region and a second memory element on the sixth diffusion region, each of the first and second memory elements comprises a variable resistive element.

12. The device according to claim 11, further comprising a fourth wiring on the first and second memory elements.

13. The device according to claim 7, wherein the first, second and third wirings are configured to be controlled in potential such that the second wiring takes a first level when either one of the first and third wirings takes the first level and that the second wiring takes a second level when both the first and third wirings take the second level.

14. The device according to claim 13, wherein the first and third wirings are configured to be controlled in potential independently of each other.
